(19) United States
(12) Patent Application Publication
(10) Pub. No.: US 2026/0100716 A1
(43) Pub. Date: Apr. 9, 2026

(54) Antirelaxation Coatings for Vapor Cells

(71) Applicant: Quantum Valley Ideas Laboratories, Waterloo (CA)

(72) Inventors: Rajesh Pandiyan, Kitchener (CA); Sanyasi Bobbara, Waterloo (CA); Su-Peng Yu, Waterloo (CA); Sohail Abdul Jalil, Kitchener (CA); Adam Sibenik, Waterloo (CA); Somayeh M.A.Mirzaee, Kitchener (CA); James P. Shaffer, Kitchener (CA)

(73) Assignee: Quantum Valley Ideas Laboratories, Waterloo (CA)

(21) Appl. No.: 19/352,197

(22) Filed: Oct. 7, 2025

Related U.S. Application Data
(60) Provisional application No. 63/704,734, filed on Oct. 8, 2024.
(60) Provisional application No. 63/810,911, filed on May 23, 2025.

(51) Int. Cl. H03L 7/26; G01R 33/02; G04F 5/14

(52) U.S. Cl. CPC H03L 7/26; G01R 33/02; G04F 5/14

(57) ABSTRACT

In a general aspect, antirelaxation coatings are disclosed for coating the interior surfaces of vapor cells. In certain aspects, a vapor cell includes a dielectric body having interior and exterior surfaces. The interior surface defines a cavity in the dielectric body, and the exterior surface defines an opening to the cavity. The vapor cell also includes an antirelaxation coating that is disposed on the interior surface of the dielectric body and includes an organosilane material. The vapor cell additionally includes a vapor or a source of vapor residing in the cavity as well as an optical window that covers the opening to the cavity. The optical window has a surface bonded to the exterior surface of the dielectric body to form a seal around the opening. The vapor or the source of vapor includes alkali metal atoms.

### CROSS-REFERENCE TO RELATED APPLICATIONS

This application claims priority to U.S. Prov. Pat. App. No. 63/704,734, which was filed on Oct. 8, 2024, and entitled, “Forming a Bonded Interface Using Plasma-Activated Surfaces.” This application also claims priority to U.S. Prov. Pat. App. No. 63/810,911, which was filed on May 23, 2025, and entitled, “Anti-Relaxation Coatings for Vapor Cells.” The disclosures of the above-referenced priority applications are incorporated herein by reference.

### GOVERNMENT LICENSE RIGHTS

This invention(s) was made with U.S. government support within the SaVANT program under Contract No. HR001120S006A with the Defense Advanced Research Projects Agency (DARPA) of the Department of Defense (DoD). The invention(s) was also made with U.S. government support within the EQSTRA program under Contract No. HR0011-25-3-0094 with the DARPA of the DoD. The government has certain rights in the invention(s).

### BACKGROUND

The following description relates to antirelaxation coatings for vapor cells.

Vapor cells can be manufactured by sealing a vapor within an enclosed volume. The vapor can be used as a medium to interact with electromagnetic fields that are incident on the vapor cell. Beams of light generated by lasers can be directed through the vapor to probe and measure the response of the vapor to the electromagnetic fields. In this way, a vapor cell can be used to determine properties of the electromagnetic fields.

### DESCRIPTION OF DRAWINGS

FIG. 1A is a schematic diagram, in exploded perspective view, of an example vapor cell having a dielectric body and an optical window;

FIG. 1B is a schematic diagram, in perspective view, of the example vapor cell of FIG. 1A, but in which the optical window is bonded to the dielectric body;

FIG. 1C is a schematic diagram, in exploded perspective view, of the example vapor cell of FIG. 1A, but in which a source of vapor resides in a cavity of the example vapor cell;

FIG. 1D is a schematic diagram, in exploded perspective view, of the example vapor cell of FIG. 1A, but in which a source of vapor resides in a second chamber of a cavity of the example vapor cell;

FIG. 1E is a schematic diagram, in exploded perspective view, of the example vapor cell of FIG. 1A, but in which the optical window includes an antirelaxation coating on its covering portion;

FIG. 1F is a schematic diagram, in exploded perspective view, of the example vapor cell of FIG. 1A, but in which the dielectric body includes a channel having a porous layer therein;

FIG. 1G is a schematic diagram, in perspective view, of the example vapor cell of FIG. 1F, but in which the optical window is bonded to the dielectric body;

FIG. 1H is a schematic diagram, in cross-section view, of the example vapor cell of FIG. 1G, showing a depth of the channel in the dielectric body and a height of the porous layer;

FIG. 2A is a schematic diagram, in exploded perspective view, of an example vapor cell having two optical windows;

FIG. 2B is a perspective view of the example vapor cell of FIG. 2A, but in which both optical windows are bonded to a dielectric body of the example vapor cell;

FIG. 3 is a flowchart of an example process for bonding an optical window to a dielectric body of a vapor cell;

FIG. 4 is a flowchart of an example process for forming an antirelaxation coating on a surface of a vapor cell;

FIG. 5 is a flowchart of an example 500 of the formation processes for forming a gettering element in a dielectric body of a vapor cell;

FIG. 6A is an example surface of a layer of silicon oxide grown by thermal oxide;

FIG. 6B is a scanning electron micrograph of an example cross-section of a layer of silicon oxide grown by thermal oxide;

FIG. 7 is a graph, in perspective view, of an example of an OTS coating on an oxidized silicon surface;

FIG. 8 is a schematic diagram showing an example fabrication process for vapor cells with organosilane coatings;

FIG. 9A is an image of an example microfabricated 4″ wafer of cells with 150-nm dry thermal oxide;

FIG. 9B is a scanning electron micrograph of an example of a smooth silicon cavity side wall after optimization of the HNA process with etch time of 7 mins;

FIG. 10A is a photograph showing the contact angle of an example liquid cesium droplet on an MEMpax glass substrate;

FIG. 10B is a photograph showing the contact angle of an example liquid cesium droplet on a Si/SiO₂ substrate with a 150-nm dry oxide surface layer.

FIG. 11A is a schematic diagram, in perspective view, of an example vapor cell during fabrication in which complete OTS coverage is on a glass window and side wall surfaces of a base frame;

FIG. 11B is a schematic diagram, in cross section view, of the example vapor cell of FIG. 11A;

FIG. 11C is a schematic diagram, in perspective view, of the example vapor cell of FIG. 11A, but during fabrication and in which OTS coats the side wall surfaces and a glass window;

FIG. 11D is a photographic image, in perspective view, of an example of an Cs alkali dispensed OTS SAMs-coated vapor cell with complete OTS coverage on the glass window and base frame fabricated using low temperature bonding process;

FIG. 12A presents a graph showing an example of a saturated absorption spectrum of hermetically sealed OTS coated vapor cell, measured immediately after the top glass window bonding;

FIG. 12B is a schematic diagram, in cross-section view, of an example of a selective laser ablation process in the bonded layers of a vapor cell;

FIG. 12C is a photomicrograph showing an example of a laser ablated area in a vapor cell;

FIG. 12D is a scanning electron micrograph of an example of a silicon porous layer formed on a side wall of a silicon wafer;

FIG. 12E is a scanning electron micrograph of the silicon porous layer of FIG. 12D, but at higher magnification;

FIG. 13A is a graph showing an example of a saturated absorption spectrum of an OTS-coated Cs alkali vapor cell, measured after a selective laser ablation process;

FIG. 13B is a graph showing an example of an EIT line shape and FWHM measured from a two-photon sensing scheme;

FIG. 13C is a graph showing an example of an EIT line shape and FWHM measured from a three-photon sensing scheme;

FIG. 14A is a graph showing an example of an XPS depth profile on a surface of an OTS-coated vapor cell; and

FIG. 14B is a graph showing an example of an XPS depth profile on a uncoated surface of a vapor cell.

### DETAILED DESCRIPTION

In some aspects of what is described, antirelaxation coatings are used to coat the surfaces of vapor cells. The vapor cells are configured to sense radio frequency (RF) fields and include an internal cavity for containing a vapor. The vapor may include a vapor having a Rydberg electronic state, such as a vapor of Group IA atoms. In some implementations, the antirelaxation coatings coat (e.g., cover) one or more surfaces of the internal cavity. Such surfaces may include a surface of an optical window of the vapor cell. Moreover, the antirelaxation coatings may be formed of a material that is stable at temperatures up to at least 100° C. For example, the antirelaxation coatings may be formed of an organosilane material, such as octadecyltrichlorosilane (OTS), that is stable to temperatures up to about 170° C. In some implementations, the antirelaxation coatings allow the vapor cells to be fabricated at temperatures that improve the strength and hermetic capabilities of seals in the vapor cells. Other advantages are possible.

In some aspects of what is described, a vapor cell may be manufactured with a gettering element to remove gas species from an internal cavity of the vapor cell. The internal cavity may contain a vapor having a Rydberg electronic state, such as a vapor of Group IA atoms. The gettering element may therefore be operable to remove impurities from the vapor, thereby improving the performance of the vapor cell. In some cases, the impurities result from the bonding processes used to bond an optical window of the vapor cell to an external surface of the dielectric body to form a bonded interface. In some cases, the impurities result from molecules desorbing from a surface of the internal cavity, such as from an antirelaxation coating disposed on the surface. The gettering element may, for example, correspond to a channel in a dielectric body of the vapor cell. The channel includes a porous layer that is configured to absorb a gas species from the internal cavity. The gas species may include water vapor, hydrogen, carbon dioxide, a volatile organic compound, or some combination thereof. However, other constituents are possible (e.g., oxygen). In these cases, the channel extends along a portion of a bonded interface of the vapor cell. For instance, the channel may extend along a portion of the bonded interface between open and closed channel ends, with the open channel end being adjacent to the cavity. However, other configurations are possible for the channel.

Atomic vapor cells may be used as components in precision measurement systems, such as chip scale atomic clocks, atomic magnetometers, and Rydberg atom RF field sensors. The performance of the atomic vapor cells in these devices may be improved by controlling or eliminating certain processes. For example, in atomic magnetometers, it may be highly advantageous to prevent the depolarization of the atomic nuclear spin, thereby increasing integration times. As another example, for clocks and Rydberg atom-based RF field sensors, it may be highly advantageous to control the environment of vapor atoms in the internal cavity. For instance, the electric fields in the sensors can be controlled and preferably eliminated. Likewise, the collisions of the vapor atoms with contaminate gases can be controlled or eliminated.

The precision of these devices depends on the relaxation time of the appropriate atomic coherence. Longer relaxation times lead to higher precision. Spin-polarized alkali-metal atoms can be completely depolarized by collisions between the spin-polarized atoms and vapor cell cavity walls. Antirelaxation vapor cell wall coatings (ARC) can prevent depolarizing wall collisions in magnetometers. For Rydberg atom-based sensing, polymer coatings, alkanes, alkenes, and organosilanes can be used to passivate the internal cavity of a vapor cell. This passivation may suppress electric fields caused by alkali atoms (as well as other species of atoms and molecules) bonding to the internal surfaces of the vapor cell. Electric fields in MEMs vapor cells can lead to inhomogeneous broadening, which also causes dephasing.

In some aspects, manufacturing processes are disclosed for fabricating MEMs alkali vapor cells with antirelaxation coatings, making them well-suited for applications like Rydberg atom-based sensors, atomic clocks, and magnetometry. Most known, antirelaxation coatings are based on long chain polymers (e.g., waxes) whose performance generally degrades at temperatures higher than 80° C. The low damage temperature of these coatings prevents their compatibility with commonly used bonding techniques for MEMs devices, such as anodic bonding. In addition to degrading antirelaxation coatings, high temperatures during bonding can also drive unwanted gases into the vapor cell cavity. These unwanted gases can collide with the atoms of interest (also leading to decoherence), making low temperature bonding advantageous from this perspective.

In some implementations, the antirelaxation coatings include an organosilane material. An example of this material is octadecyltrichlorosilane (OTS), which can be represented chemically by CH₃(CH₂)₁₇SiCl₃. In many cases, organosilane coatings show an increased temperature stability compared to alkene and alkane coatings due, in part, to their chemical bonds to the substrate surface. OTS layers are stable up to about 170° C. in the presence of Cs vapor, above which degradation may occur. They can be applied as self-assembled monolayer (SAM) or multilayers. Moreover, they are compatible with the contact-bonding processes described in U.S. Pat. No. 10,859,981 entitled “Vapor Cells Having One or More Optical Windows Bonded to a Dielectric Body”. Such processes can ensure the hermetic, ultra-high vacuum sealing of MEMs vapor cells at low temperatures (e.g., about 140° C.). In these processes, the surface and interfacial properties can be tailored, using plasma activation and cleaning to support strong, hermetic sealing of the materials, capable of supporting a high or ultrahigh vacuum environment.

Some aspects of what is described include processes for applying OTS as an antirelaxation wall coating for vapor cells. Such processes can, in some cases, use a low-temperature approach to bond vapor cells for a glass//SiO₂/silicon/SiO₂//glass architecture. This bonding approach may, in certain cases, include pre-surface modification of the interfacial layers using plasma activation, followed by a selective (locally) laser ablation mechanism of the SiO₂/Si substrate. The resulting ablated substrate can be used to getter any background gases from the OTS coatings, thereby lowering the background pressure and improving the vacuum performance inside the cell. In some implementations, the vapor cells may be fabricated by bonding layers of aluminum oxide (e.g., Al₂O₃) and titanium oxide (e.g., TiO₂) and applying an OTS antirelaxation coating. However, layers of other materials are possible (e.g., glass, quartz, fused silica, etc.). For the chip-scale cell design, a single-cavity (e.g., size of 4 mm×4 mm) approach can be chosen for each vapor cell. In this approach, liquid alkali droplets are confined to a side pocket/reservoir connected through a narrow channel (e.g., 50-100 μm in diameter). The side pocket/reservoir is separated from the internal cavity that features the antirelaxation wall coating. This configuration avoids depolarization of the spin polarized alkali atoms in the probe chamber (e.g., the internal cavity) that could occur if the atoms collided with (or were absorbed by) alkali droplets present on the chamber walls, similar to collisions with an uncoated cell wall.

In some implementations, manufacturing processes may include one or more of the following steps: (1) Material selection and vapor cell design, (2) Laser micromachining of the silicon wafer, (3) Etching processes of the silicon side walls, (4) SiO₂ dry thermal oxidation of silicon wafer, (5) anodic bonding of base chip frame (Si/SiO₂//Glass), (6) wet coating of an ultra-thin/self-assembled monolayer of OTS with low roughness without aggregates on top of the thermal oxide and glass capping wafer, (7) vapor cell filling, (8) low temperature bonding the wafer pairs of glass/OTS/SiO₂/Silicon substrate at about 140° C., and (9) selective (e.g., locally) laser ablation of SiO₂/Si substrate, followed by the spectroscopic characterization of the fabricated vapor cell. The morphology, wettability, and chemical bonding nature of OTS coatings can be characterized using an atomic force microscope (AFM), contact angle measurements, and X-ray photoelectron spectroscopy (XPS), respectively. Examples described here demonstrate the effectiveness of integrating internal coatings of OTS self-assembled monolayers into vapor cells. Such monolayers can be used to passivate and protect the internal surfaces of the vapor cells from reaction with alkali atoms and collisional relaxation of the nuclear spin of the alkali atoms. The monolayers can thus pave the way for improved sensitivity and reliability in advanced applications in the field of atomic sensing technologies.

In many implementations, the central component of a Rydberg atom-based radio frequency (RF) sensor is a vapor cell that contains a vapor of atoms (e.g., a vapor of Group IA atoms, such as a vapor of Cs atoms, a vapor of Rb atoms, etc.). Microfabricated (e.g., MEMs) vapor cells have spurred on a new generation of devices based on atomic vapors, where atomic spectroscopy can be used to readout time, frequency, inertial forces, magnetic fields and electric fields. MEMs vapor cells can be used for Rydberg atom sensing because of, for example, their greater uniformity and controlled methods of construction, especially when compared to glass blown vapor cell. Moreover, large numbers of MEMs vapor cells may be required for products if arrays of vapor cells are necessary for applications.

Vapor cell design and fabrication for Rydberg atom-based RF sensors can be complicated because Rydberg atoms (e.g., atoms excited into a Rydberg electronic state) are uniquely sensitive to electric fields and collisions. This sensitivity can mean that they can experience line shifts and broadening from these phenomena that reduces sensitivity and reproducibility. In many cases, the size of the vapor cell is comparable to the wavelengths of RF electromagnetic fields, adding to the design intricacy. For a Rydberg atom-based sensor that is intended for use over a broad frequency range (e.g., a range of about 100 GHz), the vapor cell, despite its dielectric construction, can easily transition from the Rayleigh to Mie scattering regime, or even the optical scattering regime. The possibility of such transitions requires the meticulous engineering of vapor cells. Moreover, the form of a vapor cell matters for Rydberg atom-based RF sensors. For example, line broadening, frequency shifts, RF scattering, unintended alkali metal coatings of the vapor cell walls, and manufacturing difficulties (e.g., bonding, outgassing, etc.) can complicate efforts to capitalize on the unique advantages offered by Rydberg atom-based RF sensors. Similar issues exist for vapor cells adapted for use in atomic clocks, magnetometers and gyroscopes. The manufacturing, design, wall coatings, and production scaling challenges make the development of new and better bonding processes for vapor cell sensors a pressing need. Vapor cells for RF sensing can be plagued by electric fields that cause shifts and broadening of the spectral lines that reduce their sensitivity and accuracy. Background gases remaining in the vapor cell can also broaden the spectral lines.

In some cases, systems and techniques disclosed herein allow for the microfabrication of alkali vapor cells that feature uniform, stable, and reproducible OTS self-assembled monolayers. In many cases, these monolayers serve as passivation coatings for Rydberg atom sensing. The monolayers can also serve as antirelaxation wall coatings for magnetometry when applied to the oxidized silicon substrate of an internal vapor cell cavity. In some cases, the outgassing of gases that typically result from OTS molecules cross-linking and/or interacting with byproducts generated during the low temperature hermetic sealing process (e.g., T˜140° C.) can be reduced or minimized. The low temperature bonding process itself further reduces the outgassing from the vapor cell materials, thereby lowering the internal gas pressure so as to reduce collisional dephasing effects. Such techniques can be used to manufacture miniaturized and mass-produced MEMs vapor cells. These vapor cells can have enhanced coherence times and improved performance metrics for precision sensing applications.

For Rydberg atom-based sensing, the efficacy of microfabricated alkali-based vapor cells can hinge significantly on passivating the vapor cell cavity to reduce electric fields. Electric fields can cause spectral line shifts and broadening that reduces sensitivity and reproducibility. In atomic vapor cells, alkali atoms in the vapor phase can depolarize upon contact with the bare glass surface and/or the silicon internal cavity of the cell wall. During this time, the atom may experience an electromagnetic interaction. By the time the atom leaves the surface, its spin direction may become completely randomized. Wall collisions therefore completely depolarize the atoms and can dominate all the other spin-relaxation mechanisms unless they are suppressed. This wall-depolarizing effect can be diffusive and can become more pronounced in miniaturized vapor cells under high temperatures.

Two example techniques for suppressing spin depolarization by wall surface collisions involve the use of inert buffer gases and an antirelaxation surface coating. In some instances, vapor cells that are free of buffer gas but include antirelaxation-coatings have several advantages over vapor cells that include buffer gas. Such advantages include narrowing optical line width, reducing pump light power, suppressing effects of magnetic field gradients, and avoiding spin-destruction collisions between buffer gas atoms and alkali metal atoms. While the spin polarizing collisions are important for magnetometry, alkali atoms can also be adsorbed to the surface forming a surface dipole that can produce an electric field. Antirelaxation coatings such as polymer coatings (e.g., alkanes, alkenes, etc.) and organosilane SAMs can be used to passivate the internal cavity of the vapor cell in order to suppress electric fields. These electric fields can be caused by the alkali atoms (as well as other species of atoms and molecules) bonding to the internal surfaces, thereby increasing the coherence times of Rydberg atoms in the MEMs vapor cells.

Alternative materials for antirelaxation surface coatings are based on straight-chain alkanes. One of the most representative straight-chain alkanes is paraffin. Paraffin-coatings formed by long-chain alkane molecules have been used in glass blown vapor cells where the temperature of the surfaces can be controlled so as not to destroy the coatings. Examples of such coatings include polyethylene, Paraflint (e.g., CH₃(CH₂)ₙCH₃ where n ranges from 40 to 60), and tetracontane (e.g., CH₃(CH₂)₄₀CH₃). The number of collisions between alkali-metal atoms and paraffin coatings can be up to about 10,000 before the alkali-metal atoms are depolarized. One drawback of paraffin-based coatings is their relatively low-temperature melting point of about 60-80° C. The low melting point prevents them from being used in microfabricated vapor cells due to the high temperatures (e.g., >80° C.) required by the bonding processes, such as anodic bonding. Moreover, it is highly advantageous for vapor cells to have high bond strength and bond uniformity to ensure reliable hermetic sealing. Alternative anodic bonding processes typically require high temperatures, often exceeding 300° C., which limits the application of coatings. Even in cases where anodic bonding is performed just above 200° C., compromising bond strength, the temperatures are often too high to preserve many vapor cell coatings. High temperatures can also introduce significant challenges and limitations beyond that related to the application of coatings. For instance, alkali metals, which are essential for the functioning of these vapor cells, are highly reactive and volatile at elevated temperatures. This reactivity can lead to the degradation or contamination of the alkali vapor, ultimately compromising the performance and longevity of the fabricated vapor cells. Outgassing products from the bonding can also cause collisions and dephasing of the optically prepared atomic states.

Addressing these challenges necessitates innovative fabrication strategies that balance coating integrity with the demands of microscale manufacturing. To address the above-mentioned issues, it is therefore desirable to focus on exploring surface coating materials with enhanced thermal stability, optimizing coating techniques, developing improved cell configurations, and designing cell features to getter outgassing. The resulting features are compatible with the vapor cell fabrication techniques developed for chip-scale atomic devices. In this respect, silane-terminated self-assembled monolayers of alkyl chains chemically bond to silanols on silica surfaces, to form closely packed and ordered hydrocarbon layers of thickness of about 1-2 nm, have therefore been envisioned. Applying these coatings can reduce polarization changing collisions. However, the molecules of these coatings have closed shells and can present chemically inert surfaces to prevent bonding of alkali atoms.

Octadecyltrichlorosilane (OTS) layers are particularly useful for antirelaxation coatings. In the presence of alkali atoms, such coatings of multilayer and monolayer OTS can be thermally stable up to 170° C. Achieving uniform and reproducible coating deposition within the confined and complex geometries, however, can pose a challenge. Non-uniform coatings can exacerbate decoherence rates and introduce variability across devices, undermining the reliability and scalability of production processes. On the other hand, low-temperature bonding facilitated by surface modification, coupled with hybrid anodic bonding principles, can allow the fabrication of high-quality vapor cells with minimal internal stress and enhanced durability at low temperatures. By reducing the bonding temperature, it is possible to maintain the integrity of the vapor cell wall coatings. Overcoming fabrication challenges can allow the full potential of miniaturized atomic sensors to be realized, thereby hastening their widespread adoption in next-generation technologies. This advancement not only improves the overall performance and stability of alkali-based vapor cells but also expands the range of compatible materials and device designs. Consequently, it can support the continued innovation and optimization of atomic clocks, quantum sensors, and other precision instruments that rely on alkali-based vapor cells, particularly the engineering of internal vapor cell surfaces by adding coatings.

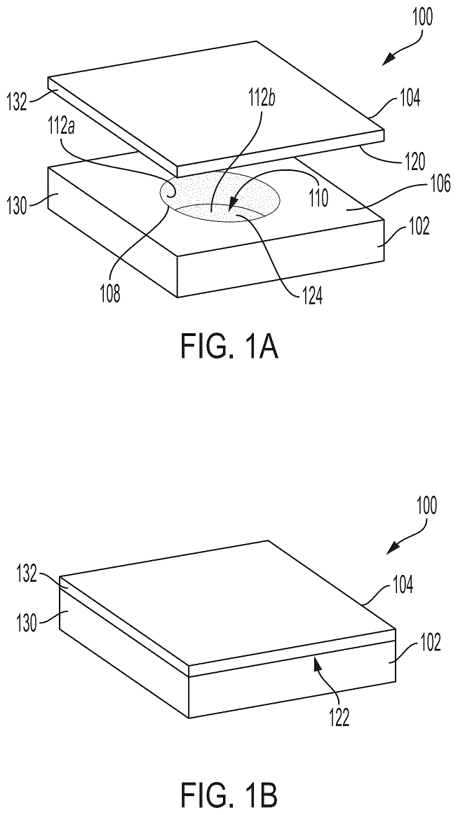

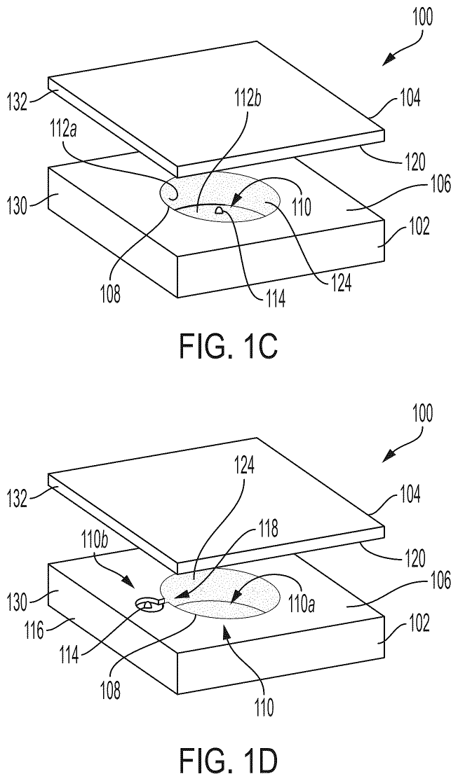

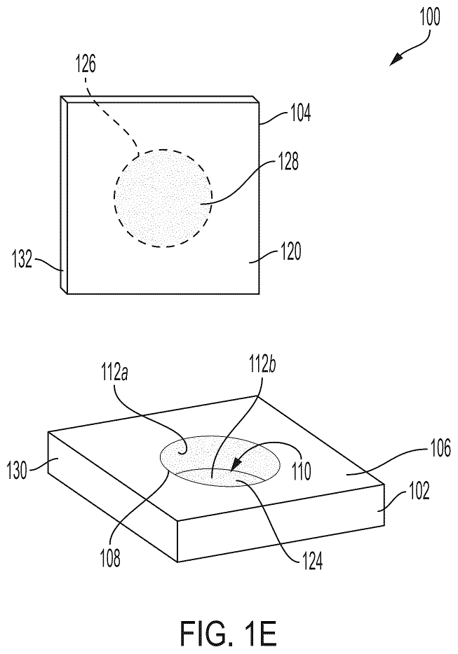

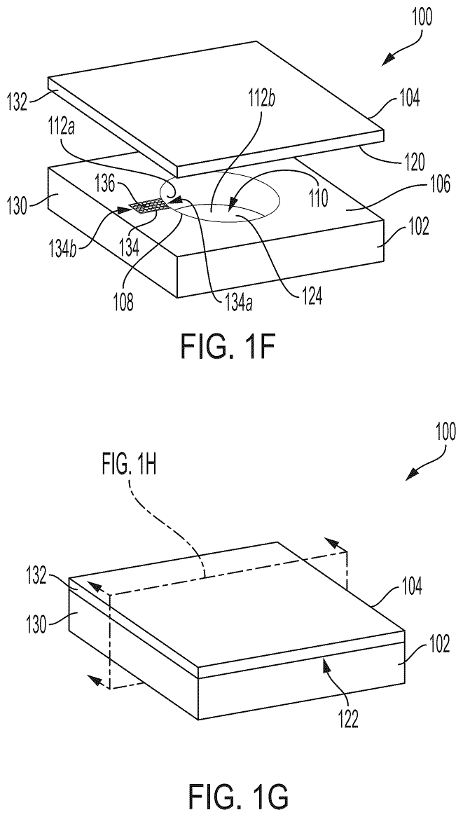

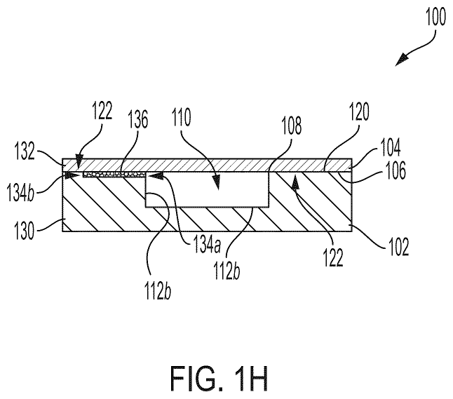

Now referring to FIG. 1A, a schematic diagram is presented, in exploded perspective view, of an example vapor cell 100 having a dielectric body 102 and an optical window 104. FIG. 1B presents a schematic diagram, in perspective view, of the example vapor cell 100 of FIG. 1A, but in which the optical window 104 is bonded to the dielectric body 102. The dielectric body 102 may be a substrate defined by planar surfaces on opposite sides of the dielectric body 102, as shown in FIGS. 1A-1B. However, other configurations are possible for the dielectric body 102. Moreover, although FIGS. 1A-1B depict the dielectric body 102 as being square, other shapes are possible. The optical window 104 may also be a substrate defined by planar surfaces. However, other configurations are possible for the optical window 104. In general, the optical window 104 includes one surface adapted to mate (or bond) with a surface of the dielectric body 102, thereby allowing a seal to form (e.g., via a bond along a bonded interface).

The dielectric body 102 may be formed of a material transparent to electromagnetic fields (e.g., from electromagnetic radiation) that are measured by the example vapor cell 100. The material may be an insulating material having a high resistivity, e.g., ρ>10⁸ Ω·cm, and may also correspond to a single crystal, a polycrystalline ceramic, or an amorphous glass. For example, the dielectric body 102 may be formed of silicon. In another example, the dielectric body 102 may be formed of a glass that includes silicon oxide (e.g., SiO₂, SiOₓ, etc.), such as vitreous silica, a borosilicate glass, or an aluminosilicate glass. In some instances, the material of the dielectric body 102 is a metal oxide material such as magnesium oxide (e.g., MgO), aluminum oxide (e.g., Al₂O₃), silicon dioxide (e.g., SiO₂), titanium dioxide (e.g., TiO₂), zirconium dioxide, (e.g., ZrO₂), yttrium oxide (e.g., Y₂O₃), lanthanum oxide (e.g., La₂O₃), and so forth. The metal oxide material may be non-stoichiometric (e.g., SiOₓ) and may also be a combination of one or more binary oxides (e.g., Y:ZrO₂, LaAlO₃, etc.). In some implementations, the material of the dielectric body 102 is a non-oxide material such as silicon (Si), diamond (C), gallium nitride (GaN), calcium fluoride (CaF), and so forth.

In some implementations, an interfacial layer is disposed on the dielectric body 102 to define a surface 106 of the dielectric body 102. The interfacial layer may be capable of bonding to the material of the dielectric body 102 (e.g., oxide, non-oxide, etc.) while also being capable of forming a bond with the optical window 104. This capability may be achieved, in many cases, by modifying an exposed surface of the interfacial layer to include reactive metal oxygen (e.g., M-O) and metal nitrogen (e.g., M-N) bonds, such as by using a sequential plasma activation process. For example, the dielectric body 102 may be formed of silicon and the example vapor cell 100 may include an interfacial layer on the dielectric body 102 that includes silicon oxide (e.g., SiO₂, SiOₓ, etc.). This interfacial layer defines the surface 106 of the dielectric body 102 and can form reactive silicon oxygen bonds (e.g., Si—O) and silicon nitrogen bonds (e.g., Si—N) when processed according to the fabrication processes described herein. As another example, the dielectric body 102 may be formed of a glass that includes silicon oxide and the example vapor cell 100 may include an interfacial layer on the dielectric body 102 that is made of amorphous silicon (e.g., a-Si). This interfacial layer defines the surface 106 of the dielectric body 102 and can also form reactive silicon oxygen bonds (e.g., Si—O) and silicon nitrogen bonds (e.g., Si—N) when processed according to the fabrication processes described herein.

The dielectric body 102 includes an exterior surface 106 that defines an opening 108 to a cavity 110 in the dielectric body 102. The exterior surface 106 may be a planar surface, as shown in FIGS. 1A-1B, although other surfaces are possible (e.g., curved). The opening 108 may be any type of opening that allows access to an internal volume of the cavity 110 and may have any shape (e.g., circular, square, hexagonal, oval, etc.). Such access may allow a vapor (or a source of vapor) to be disposed into the cavity 110 during manufacture of the vapor cell 100. The dielectric body also includes an interior surface 112 that defines the cavity 110 in the dielectric body 102. In FIG. 1A, the interior surface 112 has two sub-surfaces 112a, 112b although other numbers of sub-surfaces are possible (e.g., one, three, four, etc.). The cavity 110 extends from the exterior surface 106 into the dielectric body 102 and stops at the sub-surface 112b before extending completely through the dielectric body 102. The cavity 110 may have a uniform cross-section along its extension through the dielectric body. However, the cross-section of cavity 110 may vary along its extension in certain cases. In some implementations, the dielectric body 102 may include a metal oxide layer (e.g., a silicon oxide layer) that defines the interior surface 112. The metal oxide layer may improve the adhesion of an organosilane material to the interior surface 112 (e.g., to serve as an antirelaxation coating for the example vapor cell 100). However, other benefits are possible (e.g., ease of formation, extent of coverage, etc.).

The example vapor cell 100 includes a vapor (not shown) in the cavity 110 of the dielectric body 102. The vapor may include constituents such as a gas of Group IA atoms, a noble gas, a gas of diatomic halogen molecules, or a gas of organic molecules. For example, the vapor may include a gas of alkali metal atoms (e.g., K, Rb, Cs, etc.) and possibly also a noble gas (e.g., He, Ne, Ar, Kr, etc.). If present, the noble gas may serve as a buffer gas in certain cases. In another example, the vapor may include a gas of diatomic halogen molecules (e.g., F₂, Cl₂, Br₂, etc.) and possibly also a noble gas. In yet another example, the vapor may include a gas of organic molecules (e.g., acetylene) and possibly a noble gas. Other combinations for the vapor are possible, including other constituents. In many implementations, the vapor has Rydberg electronic states. For example, the vapor may include a gas of alkali metal atoms having Ryberg electronic states that can interact with an optical signal (e.g., a laser signal), an RF field, or both. Examples of vapors with Rydberg electronic states are described in U.S. Pat. No. 11,112,298 entitled “Vapor Cells for Imaging of Electromagnetic Fields”.

In some implementations, the example vapor cell 100 includes a source of vapor in the cavity 110 of the dielectric body 102. The source of vapor may generate the vapor in response to an energetic stimulus, such as heat, exposure to ultraviolet radiation, and so forth. FIG. 1C presents a schematic diagram, in exploded perspective view, of the example vapor cell 100 of FIG. 1A, but in which a source of vapor 114 resides in cavity 110. The source of vapor 114 may include a liquid or solid source of alkali metal atoms that generates a vapor of the alkali metal atoms when heated or irradiated. For example, the source of vapor 114 may be an alkali metal mass that is sufficiently cooled to be in a solid or liquid phase when disposed into the cavity 110. In these implementations, laser light may be used to irradiate the alkali metal mass through the optical window 104, thereby heating the alkali metal mass and causing its temperature to increase. In response, the alkali metal mass may generate (e.g., via sublimation, boiling, etc.) a vapor of alkali metal atoms, which then fills the cavity 110. However, other forms are possible for the source of vapor 114. For example, the source of vapor 114 could be a chemical compound that decomposes to produce a vapor of alkali metal atoms in response to an energetic stimulus, such as heat, irradiation, and so forth.

In some implementations, the cavity 110 includes a first chamber 110a and a second chamber 110b. This configuration may allow the example vapor cell 100 to have a region for producing vapor that is separate from a region for sensing electromagnetic fields. For example, as shown in FIG. 1D, the cavity 110 may include a channel 118 that fluidly couples the first and second chambers 110a, 110b to each other. In these cases, the source of vapor 114 resides in the second chamber 110b of the cavity 110. Moreover, the vapor of alkali metal atoms, when produced by the source of vapor 114, may diffuse from the second chamber 110b, through the channel 118, and into the first chamber 110a. In some instances, the second chamber 110b may be referred to as a “side pocket” of the example vapor cell 100.

The presence of the second chamber 110b may be useful in situations where the source of vapor 114 leaves a residue after producing the vapor of alkali metal atoms. This residue, if left in the first chamber 110a, would be undesirable as the first chamber 110a defines the sensing region of the example vapor cell 100. For example, if left in first chamber 110a, the residue could interfere with laser light entering in first chamber 110a to interact with the vapor of alkali metal atoms. The residue could also interact with the vapor (e.g. via collisions with the alkali metal atoms) to reduce the sensitivity of the example vapor cell 100 to electromagnetic fields. In some implementations, the second chamber 110b is offset from the first chamber 110a in the dielectric body 102. For example, the second chamber 110b may reside between the first chamber 110a and an outer surface 116 of the dielectric body 102. In these cases, the second chamber 110b may define a side pocket of the dielectric body 102. Moreover, the outer surface 116 may correspond to an outer side surface of the dielectric body 102, such as the outer perimeter surface 130 on a side wall of the dielectric body 102. However, other types of outer surfaces 116 may be possible.

The example vapor cell 100 additionally includes the optical window 104. As shown in FIG. 1B, the optical window 104 covers the opening 108 of the cavity 110 and has a surface 120 bonded to the exterior surface 106 of the dielectric body 102 to form a bonded interface of the example vapor cell 100. This bond forms a seal around the opening 108, and as such, the bonded interface includes the seal. In some implementations, the seal includes a metal oxynitride layer disposed along an interface 122 (e.g., the bonded interface) between the surface 106 of the dielectric body 102 and the surface 120 of the optical window 104. The metal oxynitride layer may, in certain cases, be a material having a composition of MOₓN_{y} where M represents the metal(s), x represents the stoichiometry of oxygen, and y represents the stoichiometry of nitrogen. Moreover, the metal oxynitride layer may be formed by reacting metal oxygen (e.g., M-O) and metal nitrogen (e.g., M-N) bonds on the surfaces 106, 120 of the dielectric body 102 and the optical window 104 when contacted together. If one or both of the dielectric body 102 (or an interfacial layer thereon) and the optical window 104 include silicon oxide, the metal oxynitride layer may be formed as a silicon oxynitride layer (e.g., a SiOₓN_{y} material). However, other types of metal oxynitride layers are possible. For example, if the dielectric body 102 and the optical window are both made of sapphire (e.g., Al₂O₃), the metal oxynitride layer may be formed as an aluminum oxynitride layer (e.g., a AlOₓN_{y} material). If the dielectric body 102 is made of a glass that includes silicon oxide and the optical window 104 is made of sapphire, the metal oxynitride layer may be formed as a silico-aluminum oxynitride layer (e.g., a SiₐAl_{b}OₓN_{y} material) having two metals (e.g., M=Si and Al).

The optical window 104 may be formed of a material transparent to the electromagnetic radiation (e.g., laser light) used to probe the vapor sealed within the cavity 110 of the dielectric body 102. For example, the material of the optical window 104 may be transparent to infrared wavelengths of electromagnetic radiation (e.g., 700-1000 nm), visible wavelengths of electromagnetic radiation (e.g., 400-7000 nm), or ultraviolet wavelengths of electromagnetic radiation (e.g., 10-400 nm). Moreover, the material of the optical window 104 may be an insulating material having a high resistivity, e.g., ρ>10⁸ Ω·cm, and may also correspond to a single crystal, a polycrystalline ceramic, or an amorphous glass. For example, the material of the optical window 104 may include silicon oxide (e.g., SiO₂, SiOₓ, etc.), such as found within quartz, vitreous silica, or a borosilicate glass. In another example, the material of the optical window 104 may include aluminum oxide (e.g., Al₂O₃, AlₓO_{y}, etc.), such as found in sapphire or an aluminosilicate glass. In some instances, the material of the optical window 104 is an oxide material such as magnesium oxide (e.g., MgO), aluminum oxide (e.g., Al₂O₃), silicon dioxide (e.g., SiO₂), titanium dioxide (e.g., TiO₂), zirconium dioxide, (e.g., ZrO₂), yttrium oxide (e.g., Y₂O₃), lanthanum oxide (e.g., La₂O₃), and so forth. The oxide material may be non-stoichiometric (e.g., SiOₓ), and may also be a combination of one or more binary oxides (e.g., Y:ZrO₂, LaAlO₃, etc.). In other instances, the material of the dielectric body 102 is a non-oxide material such as diamond (C), calcium fluoride (CaF), and so forth.

In many implementations, the exterior surface 106 of the dielectric body 102 and the surface 120 of the optical window 104 may have a surface roughness Ra, no greater than a threshold surface roughness. The threshold surface roughness may ensure that, during hybrid bonding, pathways are not formed that leak through the seal. Such pathways, if present, might allow contamination to enter the cavity 110 and vapor to exit the vapor cell 100. In some variations, the threshold surface roughness is less than 50 nm. In some variations, the threshold surface roughness is less than 30 nm. In some variations, the threshold surface roughness is less than 10 nm. In some variations, the threshold surface roughness is less than 1 nm.

In some implementations, the example vapor cell 100 includes an antirelaxation coating 124 on the interior surface 112 of the dielectric body 102. In FIGS. 1A-1D, the antirelaxation coating 124 is shown by shading on the interior surface 112. Moreover, although FIGS. 1A-1D depict the antirelaxation coating 124 as covering the entirety of the interior surface 112, in some implementations, only a portion of the interior surface 112 may be covered (e.g., sub-surface 112a, subsurface 112b, or some other portion of interior surface 112). In some implementations, the antirelaxation coating 124 includes an organosilane material that, in many cases, includes one or more organosilane molecules. For example, the organosilane material may include organosilane molecules that have a composition represented by CH₃(CH₂)ₓSiCl₃, where x is an integer in a range from 4 to 100. However, other chemical structures and compositions are possible. In some implementations, such as shown in FIG. 1E, the surface 120 of the optical window 104 includes a covering portion 126 that extends across the opening 108 of the cavity 110. A second antirelaxation 128 coating may, in certain cases, be disposed on the covering portion 126. In many instances, the second antirelaxation coating also includes the organosilane material.

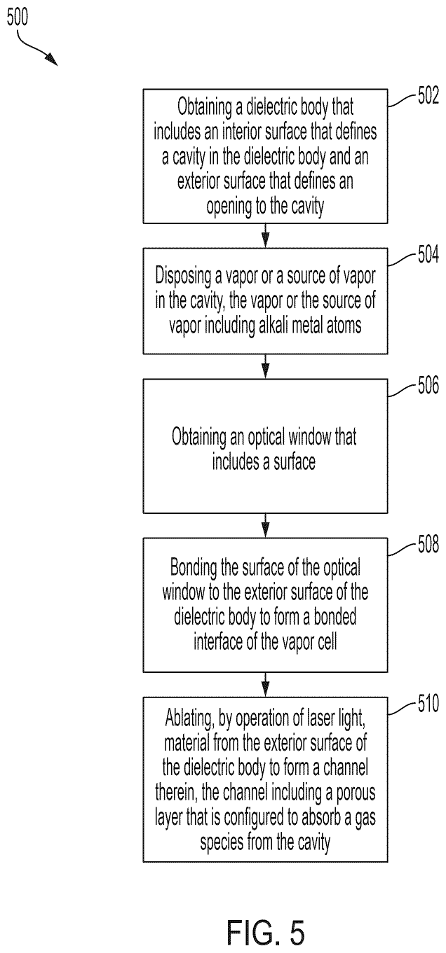

In some implementations, the organosilane material includes organosilane molecules that have a head group, a terminal group, and a spacer chain extending between the head group and the terminal group. The head group includes a silicon atom and may be configured to react with the interior surface 112, thereby adsorbing the organosilane molecules onto the interior surface 112. Moreover, in certain cases, the silicon atom has a first bond to the spacer chain and a second bond to a chlorine atom, a hydrocarbon group (e.g., a methyl group, and ethyl group, etc.), or an alkoxy group (e.g. a methoxy group, an ethoxy group, etc.). For instance, the head group may be trichlorosilane group, a methyldichlorosilane group, a dimethylchlorosilane group, or a triethoxysilane group. However, other chemical groups are possible. The terminal group may, in certain cases, include a carbon atom that has a first bond to the spacer chain and a second bond to a hydrocarbon atom or a fluorine atom. For instance, the terminal group may be a methyl group or a trifluoromethyl group. The spacer chain may, in certain cases, include an alkane chain that has one or both of a carbon-hydrogen bond and a carbon-fluorine bond. In some implementations, the organosilane material is defined by a monolayer of organosilane molecules on the interior surface 112. Further examples of the organosilane material are described below and in relation to FIGS. 5A-13.

In some implementations, the example vapor cell 100 may include one or more gettering elements for removing gas species from the cavity 110. For example, FIG. 1F presents a schematic diagram, in exploded perspective view, of the example vapor cell 100 of FIG. 1A, but in which the dielectric body 102 includes a channel 134 having a porous layer 136 therein. The channel and the porous layer 136 may define, at least in part, a gettering element of the example vapor cell 100. FIG. 1G presents a schematic diagram, in perspective view, of the example vapor cell 100 of FIG. 1F, but in which the optical window 104 is bonded to the dielectric body 102, and FIG. 1H presents a schematic diagram, in cross-section view, of the example vapor cell 100 of FIG. 1G, showing a depth of the channel 134 in the dielectric body 102 and a height of the porous layer 136.

The porous layer 136 is configured to absorb a gas species from the cavity 110, such as an impurity or contaminant species (e.g., water vapor). Such absorption may also include reacting with the gas species. As such, the porous layer 136 may act as a pump that removes (e.g., getters) the gas species from the cavity 110, and in certain cases, this pumping capability is active throughout the operational lifetime of the example vapor cell 100. Examples of the gas species include water vapor, hydrogen (e.g., H₂), carbon dioxide, and volatile organic compounds (e.g., hexane, heptane, ethanol, 2-propanol, etc.). Other constituents are possible (e.g., oxygen), including multiple constituents. In some cases, the gas species results from the bonding processes used to bond the exterior surface 106 of the dielectric body 102 to the surface 120 of the optical window 104. In some cases, the gas species results from molecules desorbing from the interior surface 112 of dielectric body 102, such as from the antirelaxation coating 124 (if present). Other sources are possible for the gas species.

In many implementations, the channel 134 and porous layer 136 are in fluid communication with the cavity 110 so that the gas species can be received from the cavity 110. For example, the channel 134 may extend along a portion of the exterior surface 106 of the dielectric body 102 between first and second channel ends (e.g., closed channel ends). In these cases, the channel 134 may be in fluid communication with the cavity 110 via a connecting channel. For instance, the connecting channel may extend along the exterior surface 106 of the dielectric body 102 between the channel 134 and the cavity 110. Alternatively, the connecting channel may extend along the surface 120 of the optical window 104 such that, when the optical window 104 is bonded to the dielectric body 102, the connecting channel extends between the channel 134 and the cavity 110, thereby fluidly coupling the channel 134 and the cavity 110 to each other. As another example, such as shown in FIG. 1F, the channel 134 may extend along a portion of the interface 122 (e.g., the bonded interface) between an open channel end 134a and a closed channel end 134b. In these cases, the open channel end 134a is adjacent to the cavity 110 (e.g., resides on the opening 108 to the cavity 110).

In some implementations, the channel 134 has a depth that ranges between 100 μm and 1000 μm. For example, the channel 134 may have a depth that is no greater than 500 μm. The depth may be selected to control the ability of the gettering element to remove the gas species from the cavity 110, such as by controlling a volume of the channel 124 that is available the porous layer 136 to fill. In some implementations, the volume of the channel 134 may be partially or completely filled by the porous layer 136, such as according to a fill percentage. For example, the porous layer 136 may completely fill the channel 136 (e.g., a fill percentage of 100%). The fill percentage may also be selected to control the ability of the gettering element to remove the gas species from the cavity 110, such as by controlling an amount of surface area of the porous layer 136 that is available to absorb the gas species. The depth of the channel 134 and the fill percentage of the porous layer 136 may be selected in combination to control the absorption capacity and pumping speed of the gettering element

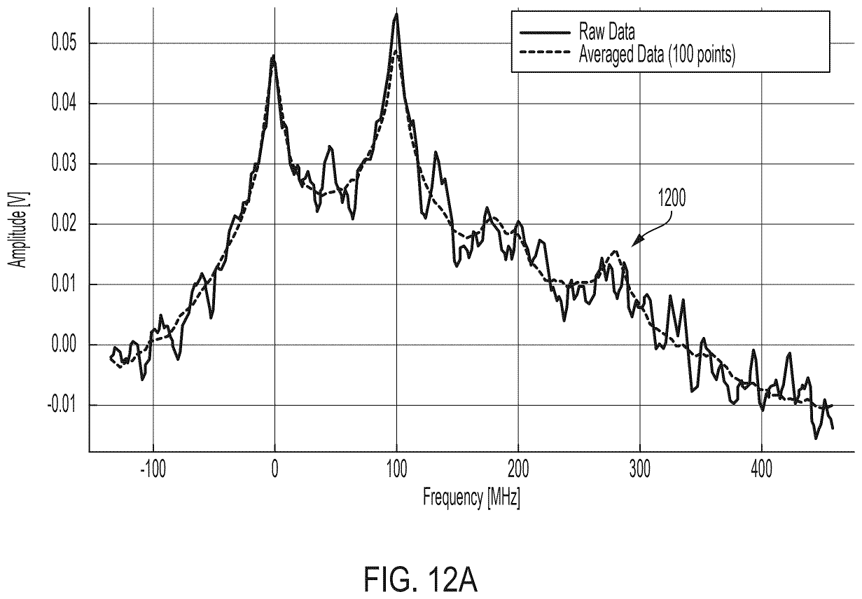

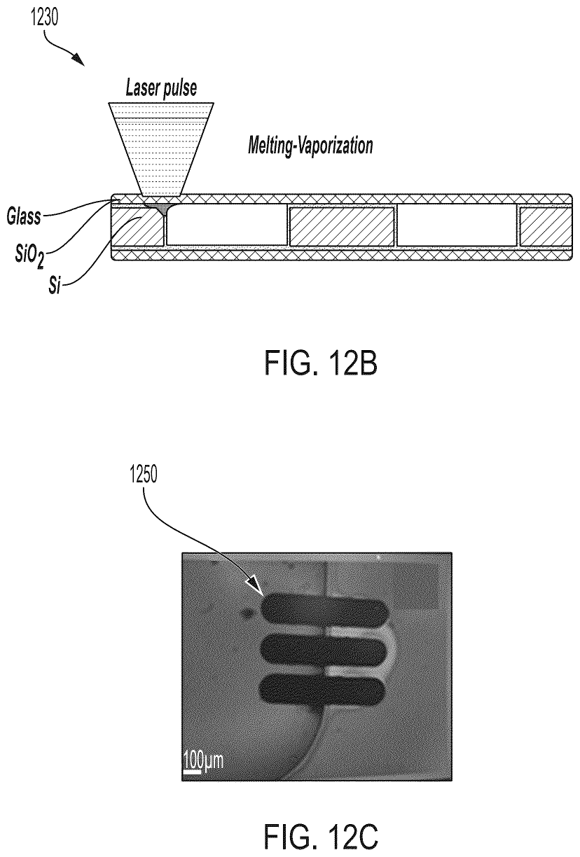

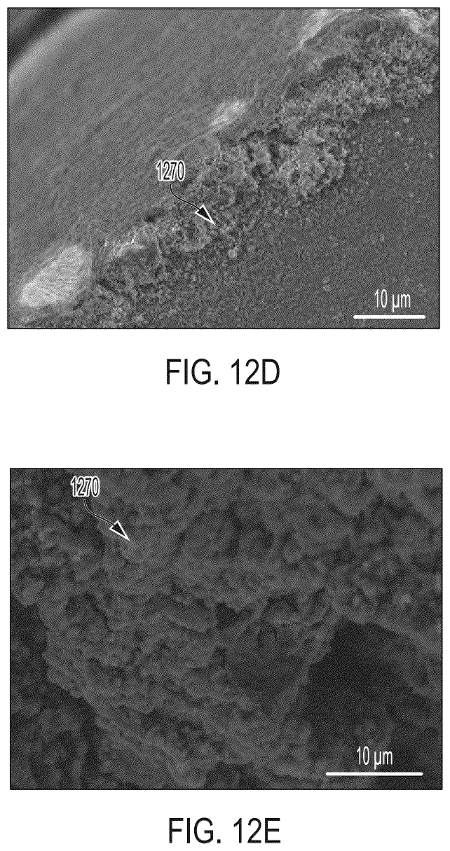

In some implementations, the channel 134 is formed by ablating the exterior surface 106 of the dielectric body 102 with laser light along the interface 122 (or portion thereof). This ablation forms a heated material that, upon cooling, forms the porous layer 136. The resulting solidified mass of the porous layer 136 may define a microstructure that can remove the gas species from the cavity 110, even in the presence of the vapor. In certain cases, the microstructure may have a bias for absorbing one or more constituents of the gas species. In some implementations, the porous layer 136 has a surface area that ranges between 200 m²/g to 1500 m²/g. For example, the porous layer 136 may have a surface area of at least 300 m²/g. In some implementations, the porous layer 136 has a void fraction that ranges from 0.2 to 0.7. For example, the porous layer 136 may have void fraction of at least 0.4. The channel 134, the porous layer 136, and example methods for their fabrication are described further in relation to FIGS. 5 and 12A-12E.

In some implementations, the exterior surface 106 of the dielectric body 102 is ablated by laser light to form first and second portions of the heated material. In these implementations, the porous layer 136 is formed by the first portion of the heated material. The second portion of the heated material, which may originate as a vaporized plume, is ejected into the cavity and operable to adsorb a second gas species. Such ejected material may include, for example, a vaporized oxide material (e.g., vaporized silicon oxide), bulk material (e.g., silicon pieces), atomic clusters (e.g., clusters of silicon atoms), nanostructures, and/or porous materials (e.g., porous silicon). The second gas species may have constituents that overlap with the gas species removed by the porous layer 136. For example, the second gas species may include water vapor, hydrogen (e.g., H₂), carbon dioxide, and volatile organic compounds (e.g., hexane, heptane, ethanol, 2-propanol, etc.). Other constituents are possible (e.g., oxygen), including multiple constituents. However, the second gaseous species need not be the same as the gas species removed by the porous layer 136. The second portion of heated material may have a microstructure (e.g., surface morphology and chemistry) that is different than the porous layer 136, and as such, may have a bias for gas constituents that are different than the bias of the porous layer 136.

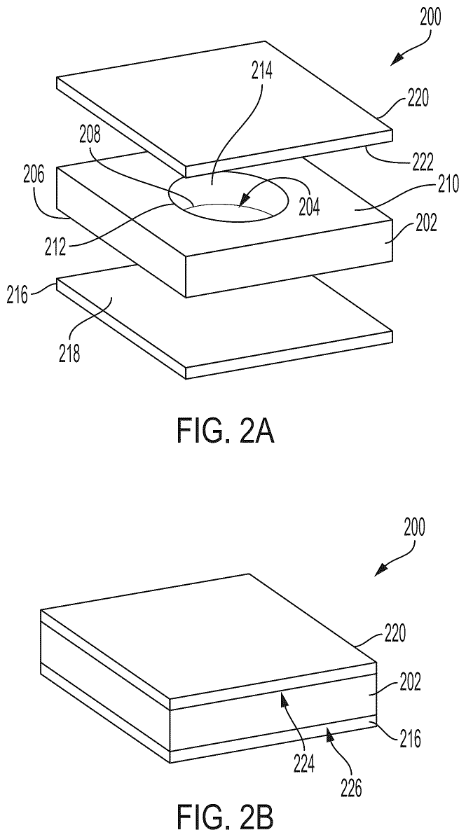

Although FIGS. 1A-1H depict the example vapor cell 100 as having a single optical window, two or more optical windows are possible for the example vapor cell 100. Moreover, in some variations, the cavity 110 may extend entirely through dielectric body 102. FIG. 2A presents a schematic diagram, in exploded perspective view, of an example vapor cell 200 having two optical windows. The example vapor cell 200 may be analogous in many features to the example vapor cell 100 shown by FIGS. 1A-1H. FIG. 2B presents a schematic diagram, in perspective view, of the example vapor cell 200 of FIG. 2A, but in which both optical windows are bonded to a dielectric body 202 of the example vapor cell 200. At least one of the bonds may include a metal oxynitride layer, such as described in relation to the example vapor cell 100 of FIGS. 1A-1H. The example vapor cell 200 includes the dielectric body 202 and a cavity 204 in the dielectric body 202. The cavity 204 extends completely through the dielectric body 202. A first exterior surface 206 of the dielectric body 202 defines a first opening 208 to the cavity 204, and a second exterior surface 210 of the dielectric body 202 defines a second opening 212 to the cavity 204. An interior surface 214 of the dielectric body 202 defines the cavity 204.

The example vapor cell 200 also includes a first optical window 216 covering the first opening 208 of the cavity 204. The first optical window 216 has a surface 218 bonded to the first exterior surface 206 of the dielectric body 202 to form a first bonded interface (e.g., interface 226) of the example vapor cell 200. The first bonded interface includes a first seal around the first opening 208. The example vapor cell 200 additionally includes a second optical window 220 covering the second opening 212 of the cavity 204. The second optical window 220 has a surface 222 bonded to the second exterior surface 210 of the dielectric body 202 to form a second bonded interface (e.g., interface 224) of the example vapor cell 200. The second bonded interface includes a second seal around the second opening 212. A vapor or a source of vapor (not shown) may, in certain instances, reside in the cavity 204 of the dielectric body 202. However, in some instances, the cavity 204 includes a first chamber, a second chamber, and a channel that fluidly couples the first and second chambers. In these instances, the source of vapor is disposed in the second chamber of the cavity 204.

The dielectric body 202 and the optical windows 216, 220 may share features in common with, respectively, the dielectric body 102 and the optical window 104 described in relation to the example vapor cell 100 of FIGS. 1A-1H. For example, the dielectric body 202 may be formed of silicon (Si), aluminum oxide (e.g., Al₂O₃), or a glass that includes silicon oxide (e.g., SiO₂, SiOₓ, etc.). In another example, one or both of first and second optical windows 216, 220 may be formed of a material transparent to electromagnetic radiation (e.g., laser light) used to probe the vapor sealed within the cavity 204 of the dielectric body 202. Other features and their combinations are possible. Similarly, the vapor and the source of vapor may share features in common with, respectively, the vapor and the source of vapor 114 described in relation to the example vapor cell 100 of FIGS. 1A-1H. For example, the vapor may include a gas of alkali-metal atoms, a noble gas, a gas of diatomic halogen molecules, a gas of organic molecules, or some combination thereof. In another example, the source of vapor may reside in the cavity 204 of the dielectric body 202, and the source of vapor may include a liquid or a solid source of alkali metal atoms that generates a vapor of the alkali-metal atoms when heated. Other features and their combinations are possible.

In some implementations, such as shown in FIGS. 2A-2B, the first and second exterior surfaces 206, 210 of the dielectric body 202 are planar surfaces opposite each other, and the surface 218 of the first optical window 216 and the surface 222 of the second optical window 220 are planar surfaces. In some implementations, the second exterior surface 210 of the dielectric body 202 and the surface 222 of the second optical window 220 have a surface roughness, Ra, no greater than a threshold surface roughness. In some variations, the threshold surface roughness is less than 50 nm. In some variations, the threshold surface roughness is less than 30 nm. In some variations, the threshold surface roughness is less than 10 nm. In some variations, the threshold surface roughness is less than 1 nm. In further implementations, the threshold surface roughness is a second threshold surface roughness, and the first exterior surface 206 of the dielectric body 202 and surface 218 of the first optical window 216 have a surface roughness, Ra, no greater than a first threshold surface roughness. The first threshold surface roughness need not be the same as the second threshold surface roughness.

In some implementations, the second seal is formed after the first seal, thereby allowing the second optical window 220 to enclose the cavity 204. In certain cases, the second seal includes a metal oxynitride layer disposed along a second interface 224 (e.g., a second bonded interface) between the second exterior surface 210 of the dielectric body 202 and the surface 222 of the second optical window 220. In certain cases, the first seal may also include a metal oxynitride layer disposed along a first interface 226 (e.g., a first bonded interface) between the first exterior surface 206 of the dielectric body 202 and the surface 218 of the first optical window 216.

In some implementations, the first seal includes an anodic bond between the first exterior surface 206 of the dielectric body 202 and the surface 218 of the first optical window 216. In some implementations, the dielectric body 202 is formed of a glass that includes silicon oxide (e.g., SiO₂, SiOₓ, etc.) and the first optical window 216 includes silicon oxide (e.g., SiO₂, SiOₓ, etc.). In these implementations, the example vapor cell 200 includes a layer of silicon (e.g., amorphous silicon) disposed between the first surface 206 of the dielectric body 202 and the surface 218 of the first optical window 216. The first seal includes an anodic bond between the layer of silicon and one or both of the first exterior surface 206 of the dielectric body 202 and the surface 218 of the first optical window 216.

The example vapor cell 100 of FIGS. 1A-1H and the example vapor cell 200 of FIGS. 2A-2B may be manufactured using bonding processes for bonding an optical window to a dielectric body. The bonding processes may, for example, be used to bond the optical window 104 to the dielectric body 102 when manufacturing the example vapor cell 100 of FIGS. 1A-1H. The bonding processes may also be used to bond the first and second optical windows 216, 220 to the dielectric body 202 when manufacturing the example vapor cell 200 of FIGS. 2A-2B. In some cases, the first optical window 216 is bonded to the dielectric body 202 using an anodic bonding process, and hybrid bonding processes are used to subsequently bond the second optical window 216 to the dielectric body 202. In many implementations, the hybrid bonding processes result in an oxynitride layer along an interface between the two bonded surfaces.

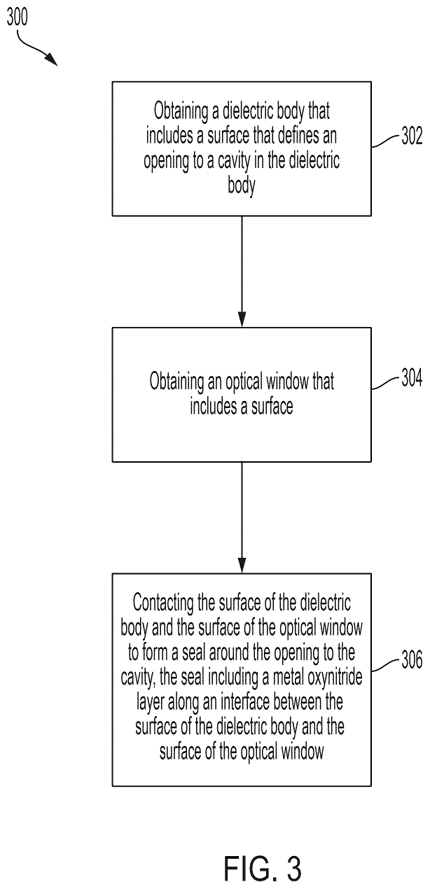

FIG. 3 presents a flowchart of an example 300 of the bonding processes for bonding an optical window to a dielectric body of a vapor cell. The example process 300 is a hybrid bonding process and may involve low temperatures (e.g., less than 200° C.). For instance, and as shown by block 302, the example process 300 includes obtaining a dielectric body that includes an exterior surface that defines an opening to a cavity in the dielectric body. The cavity is configured to contain a vapor of the vapor cell. In certain cases, the cavity may contain a source of vapor. The example process 300 also includes obtaining an optical window that includes a surface, as shown by block 304. The example process 300 additionally includes contacting the external surface of the dielectric body and the surface of the optical window to form a seal around the opening to the cavity, as shown by block 306. Such contact, in many cases, includes covering the opening of the cavity with the optical window to enclose the cavity. The seal includes a metal oxynitride layer along an interface (e.g., a bonded interface) between the surface of the dielectric body and the surface of the optical window. The metal oxynitride layer results from a reaction between the surfaces during contact. In some instances, this reaction is driven further by using a post-contact bonding process. For example, heat may be applied to the surfaces after their contact. As another example, a voltage may be applied between the surfaces after their contact. In some instances, the seal is formed at a temperature below 150° C. (e.g., T˜125° C.). In some instances, the seal is formed at a temperature between 100° C. and 150° C.

In some implementations, and before contacting the surfaces, the example process 300 may include exposing the external surface of the dielectric body and the surface of the optical window to a sequence of plasmas to produce respective altered surfaces. The sequence of plasmas may define a process in which the surfaces experience two or more plasma treatments according to a predetermined sequence. The sequence of plasmas includes an oxygen plasma and a nitrogen plasma, and in certain cases, the oxygen plasma precedes the nitrogen plasma. In these cases, the sequence of plasmas may define a process in which the surfaces are first exposed to the oxygen plasma and then to the nitrogen plasma. Exposing the surfaces to the sequence of plasmas may result in the formation of metal oxygen (e.g., M-O) and metal nitrogen (e.g., M-N) bonds on the exterior surface of the dielectric body and the surface of the optical window, thereby producing their respective altered surfaces. In these implementations, contacting the surfaces includes contacting the altered exterior surface of the dielectric body to the altered surface of the optical window. Such contact may, in certain cases, include reacting the metal oxygen and metal nitrogen bonds to form the metal oxynitride layer of the seal.

In some implementations, the example process 300 includes heating the altered surfaces of the dielectric body and the optical window to a temperature no greater than 150° C. after their contact (e.g., T˜125° C.). The temperature may, in certain cases, range between 100° C. and 150° C. In some implementations, the example process 300 includes applying a voltage between the dielectric body and the optical window after contacting the altered surfaces. The voltage may have a magnitude between 700 Volts to 1500 Volts. In certain cases, the voltage is applied while the altered surfaces are heated to the temperature. In implementations where the voltage is applied, the example process 300 may include the use of a conductive paste to improve the effect of the voltage. For example, and with reference to FIGS. 1A-1H, the dielectric body 102 and the optical window 104 may include respective outer perimeter surfaces 130, 132. In these cases, the example process 300 may include applying conductive paste to the outer perimeter surfaces 130, 132 after the altered surfaces of the dielectric body 102 and the optical window 104 are contacted. The conductive paste is configured to electrically couple the dielectric body 102 and the optical window 104. Such coupling may serve to improve the strength and/or hermicity of the seal that results when the voltage is applied.

In some implementations, the example process 300 includes disposing the vapor into the cavity of the dielectric body before contacting the surfaces. In some implementations, the example process 300 includes disposing a source of vapor into the cavity of the dielectric body before contacting the surfaces. The source of vapor may include a liquid or solid source of alkali metal atoms that produces a vapor or gas of alkali metal atoms when heated or irradiated. The example process 300 may then also include heating or irradiating the source of vapor after the seal is formed. In configurations where the second chamber is present, the source of vapor may be disposed in the second chamber before the surfaces are contacted. The second chamber may thus serve as an alternative location to the first chamber for the source of vapor. In these configurations, and after the seal is formed, the source of vapor may then be heated or irradiated, thereby allowing a vapor or gas of alkali metal atoms flow through the channel and into the first chamber. In some implementations, the example process 300 includes disposing an antirelaxation coating (e.g., a coating of paraffin) on the interior surface of the dielectric body before contacting the surfaces. Such disposal may occur before the vapor or the source of vapor is disposed in the cavity.

The example vapor cell 100 of FIGS. 1A-1H and the example vapor cell 200 of FIGS. 2A-2B may also be manufactured using formation processes for forming an antirelaxation coating on an interior surface of a dielectric body (e.g., the interior surface 112 of the dielectric body 102, the interior surface 214 of the dielectric body 202, etc.). The antirelaxation coating may be formed to cover all the interior surface, or in certain cases, be selectively formed to cover only a target portion of the interior surface.

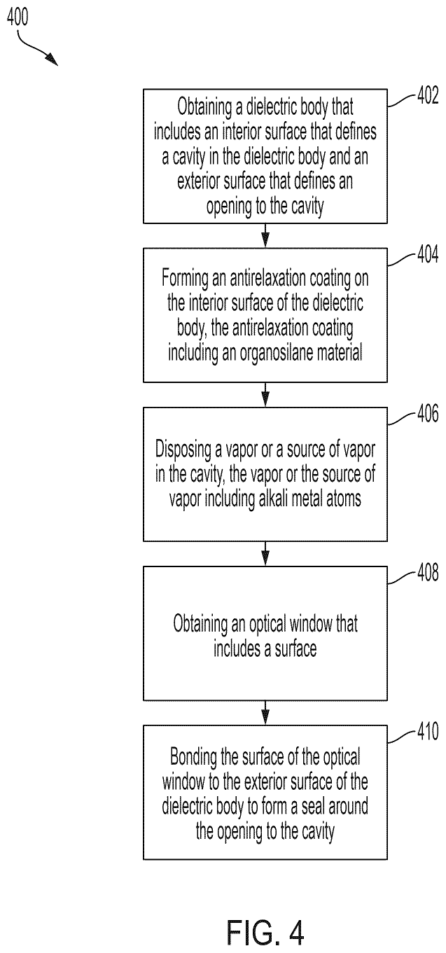

FIG. 4 presents a flowchart of an example 400 of the formation processes for forming an antirelaxation coating on a surface of a vapor cell. The example process 400 includes obtaining a dielectric body that has an interior surface and an exterior surface, as shown by block 402. The interior surface defines a cavity in the dielectric body, and the exterior surface defines an opening to the cavity. The example process 400 also includes forming an antirelaxation coating on the interior surface of the dielectric body, as shown by block 404. The antirelaxation coating includes an organosilane material, and in certain cases, forming the antirelaxation coating includes forming a monolayer organosilane molecules on the interior surface. The example process 400 additionally includes disposing a vapor or a source of vapor in the cavity, as shown by block 406. The vapor or the source of vapor includes alkali metal atoms.

The example process 400 also includes obtaining an optical window that has a surface, as shown by block 408. This surface may include a covering portion that extends across the opening of the cavity when the optical window is bonded to the dielectric body. As such, the example process 400 may, in certain cases, include forming a second antirelaxation coating on the covering portion before bonding the optical window to the dielectric body. The second antirelaxation coating includes an organosilane material. The example process 400 additionally includes bonding the surface of the optical window to the exterior surface of the dielectric body to form a seal around the opening to the cavity, as shown by block 410. Such bonding may include covering the opening to the cavity with the optical window to enclose the cavity. In certain cases, this bonding is achieved using an anodic bonding process. However, in other cases, the bonding is achieved using the example process 300 described in relation to FIG. 3. For instance, bonding the surface of the optical window to the exterior surface of the dielectric body may include exposing the surfaces to a sequence of plasmas to produce respective altered surfaces. The sequence of plasmas includes an oxygen plasma and a nitrogen plasma. The surfaces so altered may then be contacted to each other to form the seal. The seal includes a metal oxynitride layer that is formed along an interface between the altered surfaces.

In some implementations, and before forming the antirelaxation coating, the example process 400 includes contacting the interior surface with an etchant to reduce a surface roughness of the interior surface. The interior surface may, for example, have a surface roughness no greater than 5 nm after contact with the etchant. In some implementations, the example process 400 includes forming a metal oxide layer on the dielectric body to define the interior surface. The metal oxide layer may improve the adhesion of the organosilane material to the interior surface. However, other benefits are possible (e.g., ease of formation, extent of coverage, etc.). In some implementations, the interior surface of the dielectric body may include hydroxyl ligands. In these implementations, forming the antirelaxation coating includes contacting the interior surface with a solution having organosilane molecules dissolved therein. The organosilane molecules may react with the hydroxyl ligands to form the organosilane material. Forming the antirelaxation coating may also include separating the interior surface from the solution and, after separation, heating the interior surface to temperature between 100° C. and 150° C.

In some implementations, the source of vapor is disposed in the cavity before the surface of the optical window is bonded to the external surface of the dielectric body. The source of vapor may include a liquid or solid source of alkali metal atoms that generates a vapor of alkali metal atoms when heated or irradiated. In these implementations, the example process 400 may then also include heating or irradiating the source of vapor after the seal is formed. In configurations where the second chamber is present, the source of vapor may be disposed in the second chamber before the surfaces are bonded. The second chamber may thus serve as an alternative location to the first chamber for the source of vapor. In these configurations, and after the seal is formed, the source of vapor may then be heated or irradiated, thereby allowing a vapor or gas of alkali metal atoms flow through the channel and into the first chamber.

The example vapor cell 100 of FIGS. 1A-1H and the example vapor cell 200 of FIGS. 2A-2B may also be manufactured using formation processes for forming a gettering element in a dielectric body (e.g., along the exterior surface 112 of the dielectric body 102). The gettering element may, in many cases, be formed along a bonded interface, such as a bonded interface between a surface of the dielectric body and a surface of an optical window.

FIG. 5 presents a flowchart of an example 500 of the formation processes for forming a gettering element in a dielectric body of a vapor cell. The example process 500 includes obtaining a dielectric body that has an interior surface and an exterior surface, as shown by block 502. The interior surface defines a cavity in the dielectric body, and the exterior surface defines an opening to the cavity. The example process 500 also includes disposing a vapor or a source of vapor in the cavity, as shown by block 504. The vapor or the source of vapor includes alkali metal atoms. The example process 500 additionally includes obtaining an optical window that has a surface, as shown by block 506. The surface of the optical window may then be bonded to the exterior surface of the dielectric body, thereby forming a bonded interface between the two surfaces, as indicated by block 508. The example process 500 also includes ablating, by operation of laser light, material from the exterior surface of the dielectric body to form a channel therein. The channel includes a porous layer that is configured to absorb a gas species. The gettering element of the vapor cell includes the channel and the porous layer.

In some implementations, the example process 500 includes absorbing the gas species from the cavity onto a surface of the porous layer. Such absorption may involve processes of physical absorption, chemical absorption, or both. For example, absorbing the gas species may include absorbing water vapor from the cavity onto the surface of the porous layer. However, other constituents are possible, including combinations of constituents. For instance, the gas species may include water vapor, hydrogen (e.g., H₂), oxygen (e.g., O₂), carbon dioxide, volatile organic compounds (e.g., hexane, heptane, ethanol, 2-propanol, etc.), or some combination thereof.

In some implementations, ablating material from the exterior surface includes generating a heated material along a portion of the bonded interface and cooling the heated material in the channel to form the porous layer. The heated material, in certain cases, may react with at least a portion of the gas species to reduce an amount (e.g., concentration) of the gas species in the cavity. This reaction may occur while the heated material is hot (e.g., above 200° C.), and as such, the gas species (or portion of thereof) may chemisorb on a surface of the heated material. In further implementations, the heated portion includes first and second portions, with the first portion forming the porous layer. The first portion, while hot, may react with at least a portion of the gas species to reduce an amount of the gas species in the cavity. The first portion may also reduce an amount of gas species in the cavity when cooled into the porous layer (e.g., via physical absorption, chemical absorption, or both). In these implementations, ablating material from the exterior surface includes ejecting the second portion into the cavity, such as a volatized plume. The second portion is configured to absorb a second gas species from the cavity, and as such, the example process 500 may include absorbing a second gas species (e.g., water vapor) from the cavity onto a surface of the second portion. The second gas species may have constituents that overlap with the gas species removed by the first portion. For example, the second gas species may include water vapor, hydrogen (e.g., H₂), carbon dioxide, and volatile organic compounds (e.g., hexane, heptane, ethanol, 2-propanol, etc.). Other constituents are possible (e.g., oxygen), including multiple constituents.

In some implementations, and before bonding the surfaces together, the example process 500 may include disposing an antirelaxation coating on one or more surfaces of the cavity. The antirelaxation coating may include, for example, an organosilane material. In these cases, the antirelaxation coating may be formed using the example process 400 described in relation to FIG. 4. In some implementations, the surface of the optical window includes a covering portion that extends across the opening of the cavity when the optical window is bonded to the dielectric body. As such, the example process 500 may include forming a second antirelaxation coating on the covering portion before bonding the surfaces together. The second antirelaxation coating may also include an organosilane material. In such cases, the second antirelaxation coating may also be formed using the example process 400 described in relation to FIG. 4.

In some implementations, the surface of the optical window may be bonded to the exterior surface of the dielectric body using hybrid bonding processes, such as the example process 300 described in relation to FIG. 3. For example, bonding the surfaces may include exposing the surfaces to a sequence of plasmas to produce respective altered surfaces. The sequence of plasmas includes an oxygen plasma and a nitrogen plasma. In these cases, bonding the surfaces also includes contacting the altered surfaces to each other to form the bonded interface. The seal includes a metal oxynitride layer disposed along the bonded interface. In many implementations, the opening of the cavity is covered with the optical window when the surfaces are bonded to each other. If the optical window is the final optical window to be bonded to the dielectric body, the cavity may be enclosed when its opening is covered.

In some implementations, the source of vapor is disposed in the cavity before the surface of the optical window is bonded to the external surface of the dielectric body. The source of vapor may include a liquid or solid source of alkali metal atoms that generates a vapor of alkali metal atoms when heated or irradiated. In these implementations, the example process 500 may then also include heating or irradiating the source of vapor after the seal is formed. In configurations where the second chamber is present, the source of vapor may be disposed in the second chamber before the surfaces are bonded. The second chamber may thus serve as an alternative location to the first chamber for the source of vapor. In these configurations, and after the seal is formed, the source of vapor may then be heated or irradiated, thereby allowing a vapor or gas of alkali metal atoms flow through the channel and into the first chamber.

In implementations where the source of vapor is disposed in the cavity, ablating material from the exterior channel of the dielectric channel may occur after the source of vapor is heated or irradiated to generate the vapor of alkali metal atoms. However, in some implementations, the material is ablated after the source of vapor is heated or irradiated. The example process 500 is described further in relation to FIGS. 12A-12E.

In some implementations, a thermally stable, uniform, high-performance antirelaxation coating for vapor cell walls is developed that can be seamlessly integrated with the standard microfabrication processes for microfabricated alkali vapor cells. This approach leverages coatings of advanced organosilane-based self-assembled monolayers. Moreover, these coatings can be engineered to withstand moderate temperatures during hermetic sealing while maintaining their effectiveness in preserving atomic coherence and passivating the surface (e.g., making it non-reactive).

In some implementations, the formation process includes a wet chemical adsorption process whereby a plasma treated material is immersed in a solution of organic organosilane molecules. After a time required for reaction, a layer of organosilane molecules, such as a monolayer of organosilane molecules is formed. Thickness and surface roughness optimization of the surface layers, specifically by chemical polishing and thermal oxide SiO₂ growth on the silicon cavity may, in certain cases, be necessary before depositing the organosilane molecules, e.g., octadecyltrichlorosilane (OTS) molecules. This optimization may be necessary because OTS forms a self-assembled monolayer (SAM) by reacting with hydroxyl (—OH) groups on the surface. Without the SiO₂ layer, OTS may not properly adhere, resulting in poor coverage and weak bonding, which would compromise the intended properties of the coating. A smooth surface may also be required, in certain cases, to properly coat the surface for the same reasons. The interfacial layers (e.g., SiO₂) can enhance the glass//SiO₂/Si bonding strength while allowing the formation process to occur at lower temperatures. The SiO₂ layer can act as a mediator, facilitating the adhesion between the substrate and the bonding material without requiring extreme conditions. Other metal oxide layers deposited by different growth modes (e.g., Al₂O₃, TiO₂) will behave similarly. Growth techniques play a role in ensuring the uniformity and precision of the oxide layer, while controlling residual film stress, surface roughness, and stoichiometry. Moreover, by optimizing the plasma process parameters and the properties of the interfacial layer, it is possible to achieve strong, durable bonds at reduced temperatures, thereby preserving the integrity of the materials involved and improving the overall efficiency and feasibility of the low-temperature bonding process (e.g., as described in relation to the example process 300 of FIG. 3).

Maintaining a low background gas pressure in a vapor cell is beneficial in reducing collisions between alkali atoms and background gases, which might otherwise exacerbate frequency shifts and other performance issues. To address this issue, picosecond laser pulses can be used to selectively ablate a part of the cavity (e.g., the SiO₂/Si wafer) by applying ultra-short laser pulses at a wavelength of 515 nm, with laser power of about 2 W and pulse repetition rate of about 500 KHz. The laser creates porous silicon that acts to getter (e.g., acts as a pump) for background gases emitted from the OTS coating and from the bonding process. The getter reduces the background pressure in the vapor cell.

In some implementations, materials are selected for the passivation/interfacial layers in the vapor cell. For example, thermal oxide SiO₂ can be used as a material as a passivation layer for silicon and as an interfacial layer in the bonding of glass and silicon due to its excellent thermal and chemical stability. Thermal oxide SiO₂ may therefore, in many cases, be useful for creating robust interfaces in the microfabrication process. When bonding glass to silicon, SiO₂ can act as an effective intermediary layer that helps to mitigate the mismatch in thermal expansion coefficients between the two materials. This property can prevent mechanical stress build-up during thermal cycling, which would otherwise lead to delamination or cracking at the interface. Silicon oxide is compatible with both materials and thereby allows for precise control over bonding parameters such as temperature and pressure, ensuring uniform bonding across large wafer surfaces. For antirelaxation wall coatings, thermal oxide SiO₂ growth on the silicon cavity is conducted before depositing octadecyltrichlorosilane (OTS) because OTS forms a self-assembled monolayer (SAM) by reacting with hydroxyl (—OH) groups on the surface. Without the SiO₂ layer, OTS may not properly adhere, resulting in poor coverage and weak bonding, which would compromise the intended properties of the coating. Plasma treatment modifies the properties of the thermal oxide layer, enhancing its adhesion characteristics through controlled activation and functionalization. This controlled activation and functionalization may allow for the bonding of a top glass window (e.g., a final window) to the vapor cell.

In some implementations, modification of the clean silicon substrate surface starts by growing a thin film of SiO₂ by thermal oxidation. SiO₂ can be grown and/or deposited by vacuum techniques such as magnetron sputtering, evaporation or ion beam sputtering techniques, as well as plasma enhanced vapor deposition methods and atomic layer deposition methods. In many cases, silicon has a native oxide layer that can be used, but thermally grown oxide is more controlled and therefore the desired method. Thin films of SiO₂ are preferably produced by a thermal oxidation process.

In some implementations, silicon oxide grown by thermal oxidation is used over sputtering for wafer bonding applications for several reasons. For example, thermal oxidation of SiO₂ may provide a higher quality silicon oxide layer. When compared to sputtered oxide, thermal oxidation can yield a denser, more homogenous, and higher-quality SiO₂ layer. This layer results in better electrical and mechanical properties, which are crucial for wafer bonding. In some cases, thermal oxidation of SiO₂ may also provide an improved interface. Thermally grown SiO₂ can form a superior interface with the underlying silicon substrate, as it grows directly from the silicon rather than being deposited on top. Achieving a good interface can be highly advantageous in achieving a strong bonding strength. Thermal oxidation of SiO₂ may also provide precise thickness control. The thermal oxidation process allows for more precise control over the oxide thickness, which can be useful for many applications requiring a specific oxide thickness. In some cases, thermal oxidation of SiO₂ may provide a reduced defect density and better uniformity. Compared to sputtered oxides, thermal oxides typically have a lower defect density, which can enhance the bonded device's performance and reliability. Thermal oxidation can also produce more uniform oxide layers across the wafer surface compared to other vacuum techniques, which can have issues with thickness variations. Thermal oxidation of SiO₂ may additionally provide better compatibility with high-temperature processes. Thermal oxides can often withstand higher temperatures, which is beneficial for subsequent processing steps and applications requiring high-temperature stability.

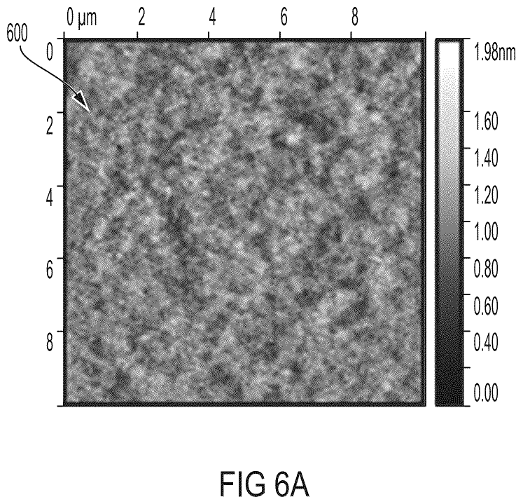

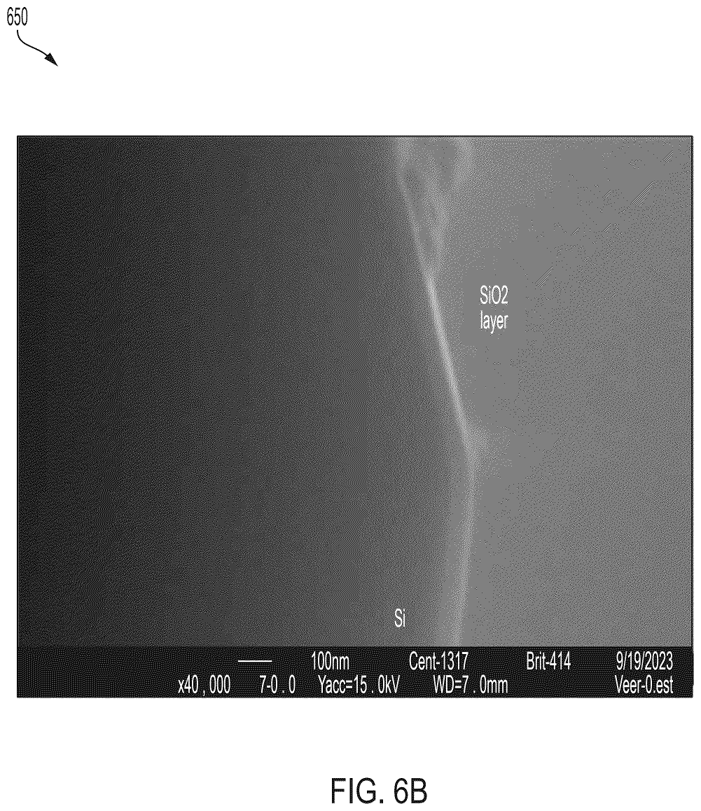

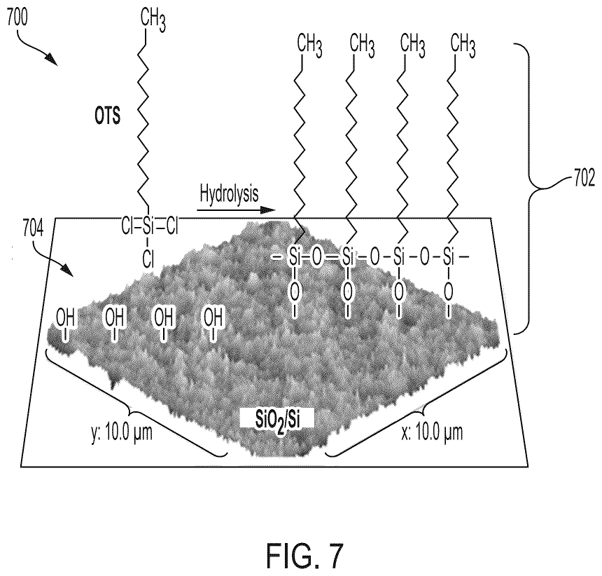

FIG. 6A presents an example surface 600 of a layer of silicon oxide grown by thermal oxide. In particular, FIG. 6A presents the surface morphology of a 10×10 μm² area of a 150-nm dry thermal oxide (SiO₂) layer taken with a Cypher Oxford Atomic Force Microscope. FIG. 6B presents a scanning electron micrograph 650 of an example cross-section of a layer of silicon oxide grown by thermal oxide. The micrograph 650 shows an image of a 50-nm dry thermal oxide layer (SiO₂). In some implementations, a high quality 150-nm layer of low stress and low roughness-silicon dioxide (SiO₂) is grown on both sides of a polished intrinsic silicon wafer of thickness 1.5 mm. The thermal oxide is a silicon dioxide film produced by the oxidation of substrate silicon, at a temperature of about 1100° C. The “dry” oxidation process may be represented by the reaction equation, Si+O₂→SiO₂. The silicon dioxide layer may form as oxygen atoms penetrate the silicon surface, oxidizing it and creating a layer of SiO₂. The surface roughness of the as-grown SiO₂ can, in certain cases, be about 0.17 nm, as shown in FIG. 7. The RMS roughness (R_{q}) value of 0.17 nm for a dry oxidized silicon dioxide (SiO₂) surface indicates that the surface has a very low level of roughness. In general, this value suggests that the surface is quite smooth on the nanoscale. The fact that such a low R_{q} value can be obtained after dry oxidation of SiO₂ is a positive indicator of high-quality oxidation and shows that the oxidation process results in a smooth and uniform oxide layer with minimal surface irregularities.

The formation technique may include selecting materials for providing antirelaxation coatings for the internal surfaces of a vapor cell. In some implementation, the materials for antirelaxation surface coatings are straight-chain alkanes. One of the most representative straight-chain alkanes is paraffin. Alkane coatings can be formed by physical adsorption. Paraffin-coatings such as polyethylene, Paraflint tetracontane (e.g., CH₃(CH₂)₄₀CH₃) can be formed by long-chain alkane molecules. Other n-alkanes include eicosane [CH₃(CH₂)₁₈CH₃], dotriacontane [CH₃(CH₂)₃₀CH₃], as well as long-chain paraffins [CH₃(CH₂)ₙCH₃), where n ranges from 40 to 60. n can also be large and vary between molecules to produce melting points that vary from 103° C. to 108° C. The number of collisions between alkali-metal atoms and paraffin coatings can be up to about 10,000 before alkali-metal atoms are depolarized. A challenge with paraffin-based coatings is their relatively low-temperature melting point of about 60-80° C. This feature prevents them from being used in microfabricated vapor cells because of the high temperatures (e.g., higher than 80° C.) of the anodic bonding processes that are typically used to hermetically seal them. In addition, a so-called ripening phase may be required, which involves annealing of the paraffin-coated cell at 50-60° C. in the presence of the alkali metal for an extended period (e.g., typically hours to days) before the vapor cell may be used. It is desirable for vapor cells to achieve robust bond strength to ensure reliable hermetic sealing, but high temperatures can introduce significant challenges and limitations for the application of alkane coatings.

In some implementations, alkenes are used as surface coatings to enhance the antirelaxation performance of alkali-metal vapor cells. Alkene coatings can be formed by physical adsorption. Unlike alkanes with long saturated carbon chain, alkenes have a C═C double bond at the end of the long carbon chain. For example, Alpha Olefin Fraction C20-24 can be fractionated at 80° C. via vacuum distillation to remove a light fraction (e.g., lighter species of the olefin molecules). The remains can be used for coating. As another example, 1-octadecene and 1-nonadecene can be used as antirelaxation coatings. In general, coatings based on alkenes can preserve approximately 106 bounces before depolarization occurs. However, antirelaxation coatings based on alkenes can be damaged once the temperature of the vapor cells exceeds 33° C., which severely limits their application.

In many implementations, the formation technique includes selecting an organosilane material for providing antirelaxation coatings for the internal surfaces of a vapor cell. Due to the limit of low working temperatures of alkanes and alkene coatings, organochlorosilanes molecules are attractive as coating materials. They can work at moderate temperatures. Moreover, organosilane self-assembled monolayers (SAMs) can be used to modify the surfaces of silicon, SiO₂, oxidized silicon nitride, quartz, and fused silica. Other material surfaces are possible. The modifications can achieve desirable surface properties such as low friction, wear resistance, anti-stiction, low surface energy, chemical inertness, and chemical affinity. The typical structure in self-assembled molecules (SAMs) can be described in three main parts, e.g., an anchoring group or head, an aliphatic carbon chain or spacer group, and a functional group also called the terminal group or tail. These three main parts are responsible for the packing structure that forms into monolayers.

In some implementations, organochlorosilane coatings can be formed by chemical adsorption, which can inhibit wall relaxation during operation of a vapor cell. The end of an organochlorosilane molecule may, for example, be a chlorosilane group. The chlorine atoms in this group can be used to react with OH groups on a silicon surface. For example, hydrogen atoms can combine with chlorine atoms to form hydrogen chloride molecules, while silicon atoms can combine with oxygen atoms to form siloxane bonds. Some of the reactive organosilane molecules that can be used to modify the surface properties and improve the surface hydrophobization of oxidized silicon substrates are, for instance, combinations of the following components: the terminal groups (e.g., trifluoromethyl —CF₃ and methyl —CH₃), the spacer chains (e.g., —(CF₂)₇(CH₂)₂—, —(CF₂)₅(CH₂)₂—, and —(CH₂)₁₇—), and surface active head groups (e.g., trichlorosilane —SiCl₃, methyldichlorosilane —Si(CH₃)Cl₂, dimethylchlorosilane —Si(CH₃)₂Cl, and triethoxysilane —Si(OC₂H₅)₃), which react with the pretreated surface to form a strong chemical bond. In some implementations, precursors can be used for the vapor-phase growth of the organosilane coating. Examples of these precursors include CF₃(CF₂)₇(CH₂)₂SiCl₂ (FDTS), CF₃(CF₂)₅(CH₂)₂SiCl₃ (FOTS), CF₃(CF₂)₅(CH₂)₂Si(OC₂H₅)₃ (FOTES), CF₃(CF₂)₅(CH₂)₂Si(CH₃)Cl₂ (FOMDS), CF₃(CF₂)₅(CH₂)₂Si(CH₃)₂Cl (FOMMS), and CH₃(CH₂)₁₇SiCl₃ (OTS). Other organochlorosilane coatings, such as butylchlorosilane (BTS) and dodecyltrichlorosilane (DTS) coatings, can also be used as antirelaxation coatings. However, in certain cases, DTS and BTS coatings may have a maximum working temperature that is lower than OTS.

In many implementations, octadecyltrichlorosilane (OTS) includes an eighteen carbon backbone (C₁₈), with a structural chemical formula C₁₈H₃₇SiCl₃, and molecular weight of 387.93 (g/mol). OTS, due to the chemical bonding to the substrate surface, may have an increased temperature stability compared to alkene and alkane coatings. For example, OTS layers can be stable up to about 180° C. in the presence of Cs vapor. Moreover, they can be applied as a self-assembled monolayer (SAM) or multilayers. The fabrication processes described herein can, in many cases, ensure hermetic, ultra-high vacuum sealing of MEMs vapor cells at low temperatures (e.g., about 140° C.). These temperatures can be used to bond OTS coated vapor cells. An example of a low temperature bonding process to form seals is described in relation to the example process 300 of FIG. 3. Taking OTS as an example, the formation process of OTS coatings on oxidized silicon surface is shown in FIG. 7. FIG. 7 presents a graph 700, in perspective view, of an example of an OTS coating 702 on an oxidized silicon surface 704. The OTS coating may be formed using the example process 400 described in relation to FIG. 4. In particular, FIG. 7 shows the formation process of OTS coatings on a 10×10 μm² area of a 150 nm dry thermal oxide (SiO₂) layer. The layer has an RMS surface roughness of 0.17 nm, as measured with a Cypher Oxford Atomic Force Microscope.

In contrast to physiosorbed coatings, OTS molecules form chemical bonds with the hydroxyl groups on a surface (e.g., a glass surface) to form coatings. The OTS monolayers produced may have a thickness of approximately 1-2 nm and a highly compact packing density, reaching up to about 4.5-5 functional groups/nm². The deposition process by which monolayers of OTS are generated can be referred to as wet chemical coating. The OTS head group (—SiCl₃) is responsible for the adsorption of the molecule to the hydroxylated surface. The long alkyl chain of methylene groups (—CH₂)₁₇ determines the intermolecular interaction that helps to promote the ordering and orientation of SAM molecules within the monolayer. The terminal methyl surface group —(CH₃) helps to determine surface properties. The methyl group, being non-polar, makes the coated surface hydrophobic, as graphically illustrated in FIG. 7. The hydrocarbon chains and the outermost chemical group —(CH₃) methyl may be similar to those in paraffins and may be inert to chemical reaction. Their inertness may be due to filled orbitals. Uniform, stable, and reproducible monolayers of OTS can be produced on oxidized silicon substrates and/or glass substrates. In many cases, the conditions for producing these monolayers include deposition under dry box conditions (e.g., dry nitrogen, dry argon, etc.), use of an anhydrous OTS solution in a solvent, and deposition on SiO₂/Si surfaces.

The deposition and the performance of an OTS coating on a silicon dioxide (SiO₂) surface can be affected by several factors that govern the monolayer formation, quality, and stability of the resultant SAMs. These factors include surface preparation, conditions of the environment, choice of solvents, OTS concentration, maturation time, immersion/coating time, baking time, and temperature. Achieving a homogenous and stable coating depends on the optimization of these factors, which govern the assembly and adhesion of OTS molecules to the SiO₂ layer.

In some implementations, an OTS concentration may be selected to deposit an OTS monolayer on a substrate. The concentration of the solution influences SAM growth and its final quality and characteristics of the SAM formed on the surface of silicon dioxide layer. For example, concentration can determine the density and organization of the OTS molecules available for adsorption that, in turn, directly affects the assembly of the coating, homogeneity, and the surface properties (e.g., hydrophobicity). When the OTS concentration is too low, insufficient molecules are available to fully cover the SiO₂ surface, resulting in an incomplete monolayer, leading to lower water contact angle and poor hydrophobic performance. On the other hand, when the OTS concentration is too high, rapid adsorption and polymerization causes multilayer formation and/or aggregates and/or isolated islands of OTS layer stacks resulting in an uneven thickness and surface roughness, which manifest itself by lower contact angle values. An OTS/solvent solution may be prepared with low toxicity, low cost, and high purity liquid solvents, such as alkanes (e.g., hexane, heptane), alcohols (e.g., ethanol), cyclohexane and toluene, at an OTS solute concentration of about 10⁻³ M. However, the concentration can vary from 10⁻¹ M to 10⁻⁴ M. For example, the concentrations of OTS may be 6.09×10⁻³ M, 7.61×10⁻³ M, 10.15×10⁻³ M, and 12.69×10⁻³ M. These concentrations correspond to OTS volume of 0.12 mL, 0.15 mL, 0.20 mL, and 0.25 mL, respectively. In some cases, a recipe for high-quality monolayer growth may include an OTS concentration of 7.61×10⁻³M, with an OTS/Hexane solution.

In some implementations, a maturation time may be selected to deposit an OTS monolayer on a substrate. The maturation time may correspond to the resting time that the OTS/Hexane solution requires to stabilise the chemical components and promote a better monolayer ordering of the OTS films. In certain cases, the maturation time may be one of the factors that regulates the spontaneous ordering processes between OTS molecules that can favour certain alignments to the substrate and thus create uniform monolayers. A pre-organisation of molecules may also exist in the solution that increases the monolayer growth rate. The maturation time may also include the time between molecule solubilisation, and the beginning of the silanization reactions once the substrate is immersed in the OTS/hexane solvent. The solubilisation phenomenon promotes better island formation and surface coverage, which means better monolayer quality. For a shorter maturation time (e.g., 5-15 mins), OTS molecules may not have enough time to fully align and covalently bond to the SiO₂ surface, leading to incomplete or less ordered monolayers resulting in possible defects. Alternatively, an excessive maturation time may increase the chances of OTS molecules forming aggregates. The presence of aggregates results in a cloudy solution, and upon coating, a rough, disordered layer with poor uniformity of the SAM will be observed. Optimizing the balance between maturation time and uniform surface coverage is useful in fine-tuning the OTS/hexane coating process on SiO₂ surfaces. For example, different maturation times of OTS/hexane solution may be used, such as 35 mins, 65 mins, 90 mins, 120 mins, and 22 hours. In some cases, high-quality OTS monolayers may be formed using a maturation time of the OTS/Hexane solution of at least 90 mins.

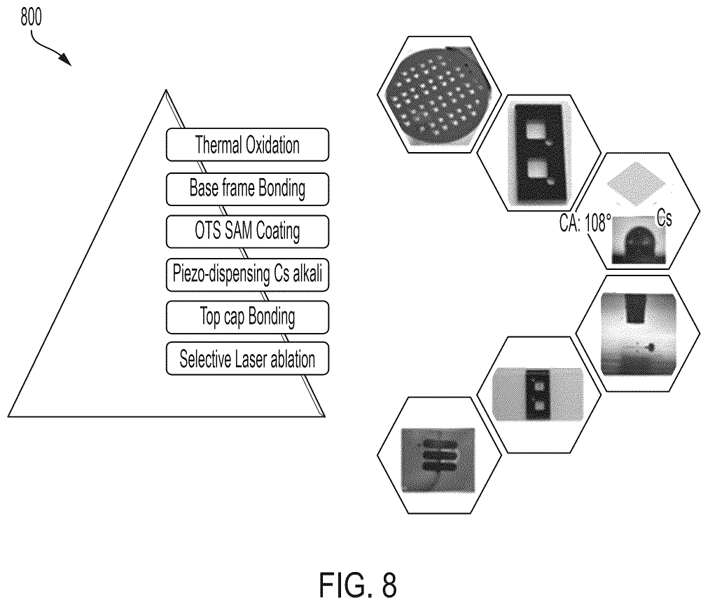

In many implementations, a vapor cell may be fabricated with an OTS coating, such as described in relation to the example process 400 of FIG. 4. The vapor cell may include, for example, a silicon frame (e.g., a dielectric body) and two glass (Mempax) windows. However, other configurations and numbers of bonding layers are possible. To fabricate the vapor cell, a window may first be bonded to a frame, thereby fabricating a so-called “base frame” in air. The base frame is coated with an OTS monolayer in a dry box environment and then later it is filled with pure Cs by a piezo-electric dispensing process. Chemical processes for filling the vapor cell with Cs are also possible. After filling the base frame, a capping window coated with OTS is placed in a bonding apparatus that is pumped down to at least 10⁻³ Torr. After the system is pumped down to the desired background pressure, the window and base frame are contacted and then bonded at about 140° C. It is the final bond of the capping window and the base frame that uses a low temperature bonding process (e.g., the example process 300 described in relation to FIG. 3). FIG. 8 presents a schematic diagram showing an example fabrication process 800 for vapor cells with organosilane coatings. The schematic diagram shows an overview of the process development for fabricating OTS coated vapor cell devices with each step briefly explained.

In some implementations, fabricating the vapor cell includes a wafer level thermal oxidation of SiO₂/Si. An example is now described. Commercially available p-type Si:B<100> orientation wafers, having a high resistivity, were obtained with both sides polished. The silicon wafer had a diameter of 4 inches and was 1.5 mm thick with a surface roughness (RMS) no greater than 0.15 nm. A p-type wafer was chosen because of its better contact properties with the glass wafer than an n-type Si wafer. The silicon wafers are first visually inspected for chips, micro-cracks, and scratches. After inspection, but prior to the thermal oxide growth on the silicon wafers, the wafers were wet cleaned using solvents swabs (e.g., laundered knitted polyester). The wafers were cleaned and rinsed with de-ionized water (DI water) to remove any particles. In order to remove particles, organic residues and other contaminants, the silicon wafers were subsequently cleaned and hydrophilized in RCA (Standard Clean-I) solution (5:1:1 mixture of H₂O:NH₄OH:H₂O₂) and (Standard Clean-II) solution (5:1:1 mixture of H₂O:HCl:H₂O₂) at a temperature of 75-80° C. for 15 min, followed by a deionized water (DI) rinse before being dried with pure Nitrogen gas (N₂) in a cleanroom environment. Modification of the clean silicon substrate surface starts by growing a thick “wet oxide” SiO₂ by thermal oxidation. Wet oxidation is generally used for growing thicker layers of SiO₂ for application such as passivation. Wet thermal oxidation can use clean steam, H₂O. For example, the steam is made by flowing a mixture of H₂ and O₂ sent through a pyrolyzer and converted into H₂O. The presence of water vapor or steam accelerates the reaction, Si+2H₂O→SiO₂+2H₂. The reactions take place at elevated temperatures around 1100° C. The H₂O molecule is smaller than the O₂ molecule and diffuses through the silicon dioxide layer faster, and hence this allows for the growth of thicker films. The objective of the wet oxidation growth of silicon is to provide a protection layer on the surface of silicon. The as-grown thickness of the wet silicon dioxide is about 1.1 μm. This layer helps to shield the underlying silicon from the physical damage during the subsequent processes of laser micromachining.

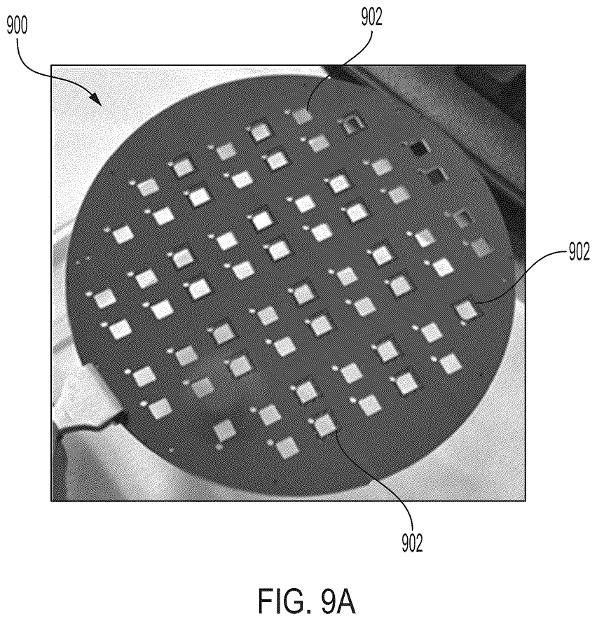

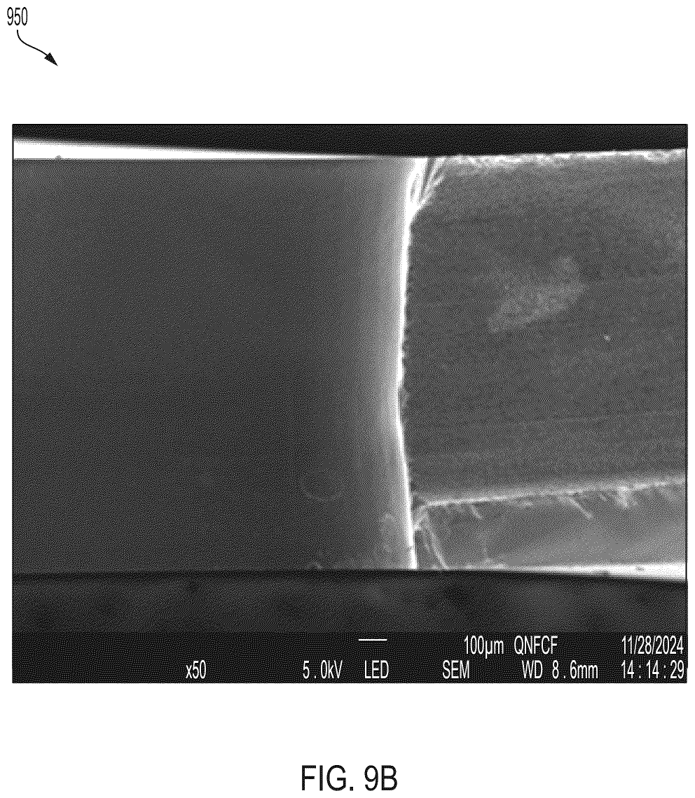

In some implementations, fabricating the vapor cell includes a laser micromachining process. The laser micromachining process may use a picosecond laser to make channels, cavities, and the side pockets in silicon coated with the SiO₂ layer. In some instances, picosecond laser may be used to form a layout in which cells are arranged in rows. Each device (e.g., 10×20 mm) includes two vapor cells independently linked through micro-channel embedded within the cell. The microchannel connects a cavity of size (e.g., 4×4 mm) and the side pocket of size (e.g., 1 mm) that hosts a dispensed Cs alkali, as shown in FIG. 9A. The SiO₂ present in this step is to protect the surface during the laser cutting process. FIG. 9A presents an image 900 of an example microfabricated 4″ wafer of cells 902 with 150-nm dry thermal oxide. FIG. 9B presents a scanning electron micrograph 950 of an example of a smooth silicon cavity side wall after optimization of the HNA process with etch time of 7 mins. An example of the HNA process is described below.

In some implementations, fabricating the vapor cell includes a side wall etching and dry thermal oxidation of SiO₂/Si. Upon completion of laser micromachining of the cell cavities, channels, and side pockets, the entire wafer can be wet cleaned using solvents. For example, the wafer cleaning procedure may begin with ultrasonication using acetone, methanol, isopropanol (IPA), and de-ionized water (DI water) in series. After ultrasonication, the wafers are dried with a nitrogen (N₂) flush. Further adherence of any particles on the surfaces from the environment are then cleaned with methanol, acetone and IPA using cleanroom swabs (e.g., laundered knitted polyester). Again, the wafers are cleaned and rinsed with DI water to remove any particles. Next, the wafer is cleaned and hydrophilized in piranha solution (e.g., a 4:1 mixture of H₂SO₄:H₂O₂) for 10 mins, followed by a deionized water (DI) rinse before being dried with pure nitrogen gas (N₂) in a cleanroom environment to remove further adherence of the debris.

The wet etching process may be used to etch the cavities in a SiO₂/Si wafer to smooth the vertical sidewalls. Several techniques have been developed to smooth the side walls. For example, anisotropic wet etching by KOH (45%) can be used. A 10-min etching in a solution heated at 75° C. can give satisfactory results, revealing the crystallographic planes. As another example, an isotropic etching recipe for the silicon side walls using an HNA (hydrofluoric acid, nitric acid, acetic acid) process may be used. In this process, HNO₃ is the oxidation agent, HF is the reducing agent, and CH₃COOH is neutralizing agent. Many factors of the HNA system affect the results during the etching process. Each microstructure and/or smoothening to be produced has particular etching parameters to achieve specific features such as high uniformity, low roughness, and repeatability. For instance, the parameter combination of an HNA composition of CH₃ COOH:HNO₃:HF (10:80:10) with an etching time of 7 mins, followed by a deionized water (DI) rinse before being dried with pure nitrogen gas (N₂) in a cleanroom environment may produce excellent results for the fabrication of silicon-based vapor cells.

The wet thermal oxide remaining after the HNA process is stripped using a buffered oxide etchant solution for 15-20 mins. The solution may be, for example, a 10:1 mixture of ammonium fluoride (NH₄F) to hydrofluoric acid (HF). The etched surface is then rinsed with deionized water (DI) and dried with pure nitrogen gas (N₂). In order to remove organic residues and other contaminants, the processed silicon wafer can be subsequently cleaned and hydrophilized in RCA (Standard Clean-I) solution (e.g., 5:1:1 mixture of H₂O:NH₄OH:H₂O₂) and (Standard Clean-II) solution (e.g., 5:1:1 mixture of H₂O:HCl:H₂O₂) at a temperature of 75-80° C. for 15 min, followed by a deionized water (DI) rinse and dried with pure nitrogen gas (N₂).

After the HNA process, a high quality 150-nm layer of low stress and low roughness-silicon dioxide (SiO₂) is grown on both sides of the polished intrinsic silicon wafer of thickness 1.5 mm. The thermal oxide is a silicon dioxide film produced by the dry oxidation of substrate silicon, at temperature around 1100° C. Details about the dry oxidation process have been described previously. Upon completion of the thermal oxidation process, a dicing saw is used to cut the SiO₂/silicon wafer into suitable sizes (e.g., dimensions of 10 mm×20 mm) for OTS coating and bonding applications. The entire wafer can also be used for a wafer scale process.

In some implementations, fabricating the vapor cell includes the anodic bonding of a base frame chip (glass//SiO₂/Si). After dicing, to remove particles and other contaminants on the substrate surface, the SiO₂ coated silicon chips and the MEMpax glass chips are cleaned ultrasonically by solvent cleaning using methanol, acetone, IPA, and DI water, each for 10 mins, and then dried with N₂ gas. Further adherence of any dust particles/residues on the surfaces from the environment were then cleaned with methanol, acetone, IPA using cleanroom swabs (e.g., laundered knitted polyester) clean and finally rinsed with DI water.

Double side polished borosilicate glass can be obtained, such as from Schott. The glass wafer may, for example, be a borosilicate MEMpax wafer having a diameter of 4 inches and a thickness of 500 μm. The surface roughness can be less than 0.2 nm. The primary constituents of the borosilicate glass are SiO₂ (81%), B₂O₃ (13%), Na₂O/K₂O (4%), and Al₂O₃ (2%). MEMpax has a high ion mobility and a thermal expansion that is closely matched to that of silicon. The silicon and glass chips are visually inspected for chips, micro-cracks, and scratches. In order to remove organic residues and other contaminants, the silicon base chip and glass chips are subsequently cleaned and hydrophilized in RCA (Standard Clean-I) solution (e.g., 5:1:1 mixture of H₂O:NH₄OH:H₂O₂) at a temperature of 75-80° C. for 15 min, followed by a deionized water (DI) rinse before being dried with pure nitrogen gas (N₂) in a cleanroom environment and then subjected to a sequential plasma activation process.

The bonding process may, in certain cases, include a plasma treatment. The plasma treatment involves the ionization of gases in a vacuum chamber to create plasma, which is used to modify the surface properties of materials. The choice of gas, power, and treatment time may be selected to influence the effectiveness of the plasma treatment. Commonly used gases include oxygen (O₂), nitrogen (N₂), argon (Ar), hydrogen (H), each providing distinct surface modifications. The power applied, typically at radio frequency (RF), may determine the energy of the plasma, affecting the rate and depth of surface interaction. Treatment time is another influential factor, as it can dictate the extent to which the surface is modified. Longer exposure generally results in more significant changes. These parameters can be controlled to achieve the desired surface characteristics, such as increased wettability, enhanced adhesion, or specific chemical functionalities.

A sequential plasma treatment, particularly the combination of oxygen (O₂), and nitrogen (N₂) plasmas, is an effective approach to surface activation. In such examples, an initial oxygen plasma treatment can be used to clean the surface and introduce reactive oxygen species (increase surface hydroxyl groups), which can form a thin oxide layer. The oxygen plasma treatment is followed by a nitrogen plasma treatment, which further modifies the surface by introducing nitrogen-containing functional groups. This sequential process creates a highly reactive and hydrophilic surface, which is beneficial for applications requiring strong adhesion, such as wafer bonding in semiconductor manufacturing. The synergy between the two plasma treatments results in enhanced surface properties that are not achievable with a single plasma treatment alone. By carefully optimizing the gas composition, power, and treatment duration for each step, the sequential plasma treatment can significantly improve the performance and reliability of bonded interfaces. The surface activation may be accomplished, for example, using a wafer level plasma cleaner. Before bonding glass to SiO₂/Si, both the glass substrate and the Si/SiO₂ chip surfaces are sequentially activated using plasma treatment, with 60 seconds each of oxygen and nitrogen plasma. The RF power of the plasma cleaner is set at around 400 Watts, and the chamber pressure maintained at about 360 mTorr. Oxygen and nitrogen gas were introduced sequentially into the plasma treatment chamber at a volume rate of about 180 and 90 sccm. After activation by plasma exposure, the pair of chips are removed from the plasma cleaner. Since the surfaces are highly hydrophilic, no further hydroxylation of the surfaces by, for example, rinsing and/or dipping an activated surface in DI water is necessary.

In many cases, the pre-contact bonding is sensitive to the cleanliness of the surface. As such, both the plasma activated surface of Si/SiO₂ and glass are placed inside a flow hood to avoid dust particles before the pre-contact bonding processes. The chips are brought into contact with the glass substrate at room temperature by placing the silicon chip with the activated surface facing upwards, while the activated surface of the glass chip is placed on top. As soon as the contact is initiated, an interference fringe pattern between the layers can be observed. To enhance the strength of the pre-contact bond, a firm pressure is applied by pressing the altered surfaces against each other. A complete, tight seal between the two activated surfaces is formed without any fringes and/or unbonded area or bubbles due to gas trapped between the glass//SiO₂ surfaces. However, in certain cases, the bonding strength may be weak because of the hydrogen bonds and low bond energy of Si—OH. An increased bond strength can be achieved when plasma activation is combined with a high and/or low temperature voltage-assisted process, referred to as a hybrid bonding process. The bonding mechanism for some example hybrid bonding processes involves an interplay between charges and chemical reactions at the interface. The resulting electrostatic interactions and chemical affinities facilitate the formation of covalent bonds, particularly siloxane bonds, at the interface. However, in many implementations—such as with the example process 300 of FIG. 3—the hybrid bonding process includes the formation of silicon oxynitrides. The hybrid bonding process involving silicon oxynitrides may be done, for example, to cap the vapor cell in vacuum by enclosing the cavity of the vapor cell with a capping window.

In some examples, during anodic bonding, the chips for the base frame are placed between two plates (e.g., graphite as anode and metallic disk as a cathode), which are connected to the DC power supply (e.g., Stanford systems, USA) to initiate the bonding processes. First, the SiO₂/Si and the glass chip are connected to the positive and negative electrodes, respectively. The bonded pairs are heated simultaneously to increase the mobility of the positive ions in the glass substrates. When the temperature is stabilized at 380° C., a DC voltage of 500-800 V is applied to the electrodes and the current between the electrodes is measured for a bonding time of 40 minutes. The anodic bonding process may be completed, for example, when the current decays to a residual value of around 0.01 mA. Anodic bonding may be used at this stage in the fabrication of the vapor cell since the base frame does not yet have any cesium in it and it is open to air for degassing. The initial bonding step is configured to create a strong, durable bond between the SiO₂ and glass. No external mechanical force is applied to put the wafers in contact during the bonding process, except for the weight of the electrode. Subsequently, the wafers are allowed to cool down to ambient temperature.

In some implementations, fabricating a vapor cell includes a preparation and OTS coating process. Before the preparation of coatings, cleaning of the base frame and top capping glass window can ensure the quality of antirelaxation coatings. Distinguishing from the cleaning process for the cells to coat alkane and alkene films, the cleaning process for the cells to coat organochlorosilanes is a pre-treatment process to generate OH groups, which react with organochlorosilanes on the interior surface of the vapor cells and capping window to form an OTS coating. The top capping glass window preparation step can include cleaning with ultrasonication using solvents. Methanol, acetone, IPA, and DI water, each for 10 mins, can be used. After removal, the window is dried with N₂ gas. The bonded base frame chip is then cleaned with methanol, acetone, and IPA using cleanroom swabs (e.g., laundered knitted polyester), then cleaned and finally rinsed with DI water. Organic residues can hinder the spontaneous ordering process of OTS molecules for the formation of monolayers. These residues may be removed from the base frame and top capping glass by subsequently cleaning and hydrophilizing in RCA (Standard Clean —I) solution (e.g., 5:1:1 mixture of H₂O:NH₄OH:H₂O₂) at a temperature of 75-80° C. for 15 min, followed by a deionized water (DI) rinse before being dried with pure nitrogen gas (N₂) in a cleanroom environment.

In some implementations, after cleaning of the bonded frame, silver (Ag) paste is applied to the sides of the bonded pair, which is then cured (e.g., at 125° C. for 1 hour) to ensure proper adhesion. The use of Ag paste after the initial bonding of the glass with the silicon can help in the multi-layer bonding process. After the first bonding step, the silver paste is applied around the bonded glass/silicon interface to create an electrical connection between the silicon layer and the next layer of glass. This connection aids the low temperature hybrid bonding of the top capping glass window. Ag paste is conductive, and its application helps to ensure that a uniform electric field can be established across the bonding interface during the window capping process. Other methods of creating a uniform field—e.g., several point electrodes or other types of conductive paste—are possible. In many cases, conductive pastes should be capable of being fully removed after completion of the vapor cell. A uniform field helps to achieve a strong and reliable bond between the top glass layer and the already bonded glass/silicon base frame structure. Both the top capping glass substrate and the already bonded glass/silicon base frame are subjected to the plasma treatment process. Each bonding surface may be activated, for example, with 60 seconds of an oxygen plasma. This plasma treatment modifies the surface properties of the thermal oxide layer, enhancing their adhesion characteristics through controlled activation and functionalization. The bonded pair, now prepared with the silver paste, is loaded into a vacuum chamber along with the top capping, glass substrate. The assembly is baked overnight to remove any moisture and/or trapped gases. After the overnight baking process, the chamber is cooled down, and the base frame and top capping glass window are ready for the OTS coating process. A thorough cleaning and outgassing step of the base frame and top glass window is required before coating with silanes to render the surface hydrophilic.

In some implementations, monolayers of OTS can be prepared from solutions of octadecyltrichlorosilane OTS—e.g., C₁₈H₃₇SiCl₃ (95%) and n-Hexane (99%) purchased from ThermoScientific chemicals. The chemicals can be used as received. The preparation step is performed in a glovebox environment to prevent OTS oxidation. Examples of different concentrations for optimizing OTS SAMs include 6.09×10⁻³M, 7.61×10⁻³M, 10.15×10⁻³M, and 12.69×10⁻³ M. These concentrations correspond to an OTS volume of 0.12 mL, 0.15 mL, 0.20 mL, and 0.25 mL, respectively. An accurate recipe for high-quality monolayer growth may be achieved, for example, using an OTS concentration of 7.61×10⁻³M in an OTS/Hexane solution. The hexane is poured in a beaker and then OTS diluted into hexane with a clean disposal syringe of 1 mL. The solution is then stirred or agitated for few minutes to ensure thorough mixing in the beaker. A few minutes of stirring the beaker and/or agitation may be performed to thoroughly mix the solution. Moreover, the prepared solution may be matured for 90 mins to stabilise the chemical components and promote a monolayer ordering in the produced OTS films. Prior to the immersion of the base frame and top glass window inside the solution, both the base frame and top glass window are transferred from the glove box to the plasma activation chamber. The surface activation can be accomplished using a wafer level plasma cleaner. Both the chip surfaces are activated using plasma treatment, with 420 seconds of an oxygen plasma. The RF power of the plasma cleaner is set at around 400 watts, and the chamber pressure maintained at about 360 mTorr. Oxygen gas is then introduced into the plasma treatment chamber at a volume rate of about 180 sccm. After activation by plasma exposure, the pair of chips are removed from the plasma cleaner and transferred to the glove box. Since the surface is highly hydrophilic, further hydroxylation of the surface is not required. Once the solution maturation time is completed, the pair of chips are immersed inside the solution following the cycles described in Table 1 below. Both the base frame and top glass window substrate are rinsed with pure hexane solvent at each intermediate cycle. All the experiments were carried out at room temperature of 23° C.

TABLE 1

| Cycle | Description |
|---|---|
| (i) | Immersion for 15 mins, followed by Hexane rinse and N₂ drying |
| (ii) | Immersion for 30 mins, followed by Hexane rinse and N₂ drying |
| (iii) | Rinsing with Hexane and N₂ drying |
| (iv) | Rinsing with Hexane and N₂ drying |
| (v) | IPA swab for base frame top surface; top glass window (optional) |
| | followed by Hexane rinse and N₂ drying |
| (vi) | Baking on a hot plate at 110° C. for 30 mins in a glove box |
| | ambient |
| (vii) | Baking at 120-140° C. inside a vacuum chamber (5 × 10⁻⁶ torr) |
| | overnight. |

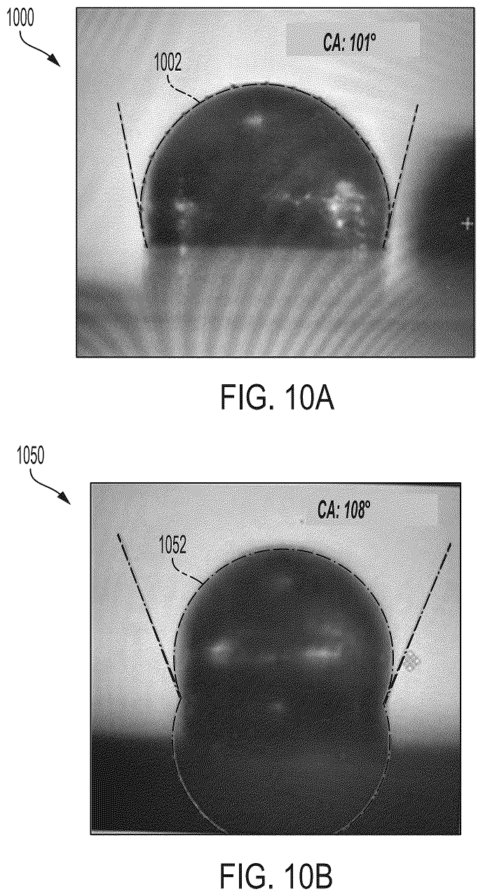

The SAMs are characterized by AFM as well as water contact angle (WCA) measurements. The contact angle of a water drop and a liquid cesium droplet on an OTS coating may, in certain cases, be used as an indicator of SAM quality. A large contact angle indicates a more hydrophobic and hence closer-packed film. OTS SAMs deposition are confirmed by WCA measurements, which indicate a contact angle of less than 5° when measured on bare RCA-cleaned and plasma-activated hydroxylated silicon and glass substrates. The contact angle of the fully covered OTS SAM is at least 100° for both the water and liquid Cs droplet. The higher contact angle on these surfaces indicates stronger repulsion against Cs wetting, likely due to the high-quality OTS layer on the glass and SiO₂ surface, which creates a dense hydrophobic monolayer. FIG. 10A presents a photograph 1000 showing the contact angle (CA) of an example liquid cesium 1002 droplet on an MEMpax glass substrate. FIG. 10B presents a photograph 1050 showing the contact angle of an example liquid cesium droplet 1052 on a Si/SiO₂ substrate with a 150-nm dry oxide surface layer.

In some implementations, fabricating a vapor cell includes dispensing an amount of Group IA atoms in the liquid state (e.g., liquid cesium). For example, after the overnight baking process, the chamber may be cooled down to room temperature, and a small quantity of pure Cs, droplet size 15-25 nL range, may be piezo-electrically dispensed into a side pocket of the OTS coated base frame structure in a glove box. However, there are other possible techniques for dispensing cesium inside the vapor cells. These techniques include: (a) direct filling of liquid Cs using a micropipette under vacuum conditions; (b) solid-state dispenser activation where a small pill-like Cs dispenser (e.g., Cs-getter pill) is placed inside the cell and activated by laser irradiation after cell sealing is completed; (c) UV photolysis of alkali azide; and (d) thermal evaporation using pure Cs metal.

In some implementations, fabricating a vapor cell includes low temperature bonding of top glass window of OTS coated vapor cell (e.g., using the example process 300 described in relation to FIG. 3). For instance, the window and base frame may be bonded next. Reducing outgassing of the vapor cell materials and the application of low temperature passivation coatings to the internal vapor cell cavity can be allowed by low-temperature (e.g., T˜140° C.) bonding. Such bonding can reduce outgassing of the vapor cell materials. By reducing the bonding temperature, it is possible to maintain the integrity of the alkali metals and avoid thermally induced damage to substrate materials as well as to the OTS SAMs. As an example of the bonding process, the Cs filled base frame assembly and window may be loaded into the bonding vacuum chamber, where the system is pumped down for 10 minutes to remove any air or moisture. Once the chamber is sufficiently evacuated (about 10⁻⁶ Torr), a manipulator is lowered to make a tight pre-contact between the base frame and the top cap glass substrate. The temperature is gradually raised to 140-150° C. in slow, controlled steps to prevent thermal stress or damage to the OTS coating. Next, a voltage of −1500 to −1700 V range is applied across the structure, initiating the final bonding step, which lasts for 90-120 minutes. The bonding process may be completed, for example, when the current passing across the layers being bonded decays to a residual value of 0.002 mA. The bonded layers are allowed to cool naturally to room temperature to prevent thermal stress and avoid breaking any bonds formed during the bonding process. Due to the polarity of the applied high voltage, the positively charged Na ions from the glass layers can move away, leaving open oxygen bonds at the interfaces between the layers. The open oxygen bonds from the glass layer can now form a molecular bond with the neighbouring silicon atoms, forming, for example, Si—O—Si and/or Si—N—Si bonds. This bond formation leads to a permanent, robust, and high hermetic tight bond between the layers.

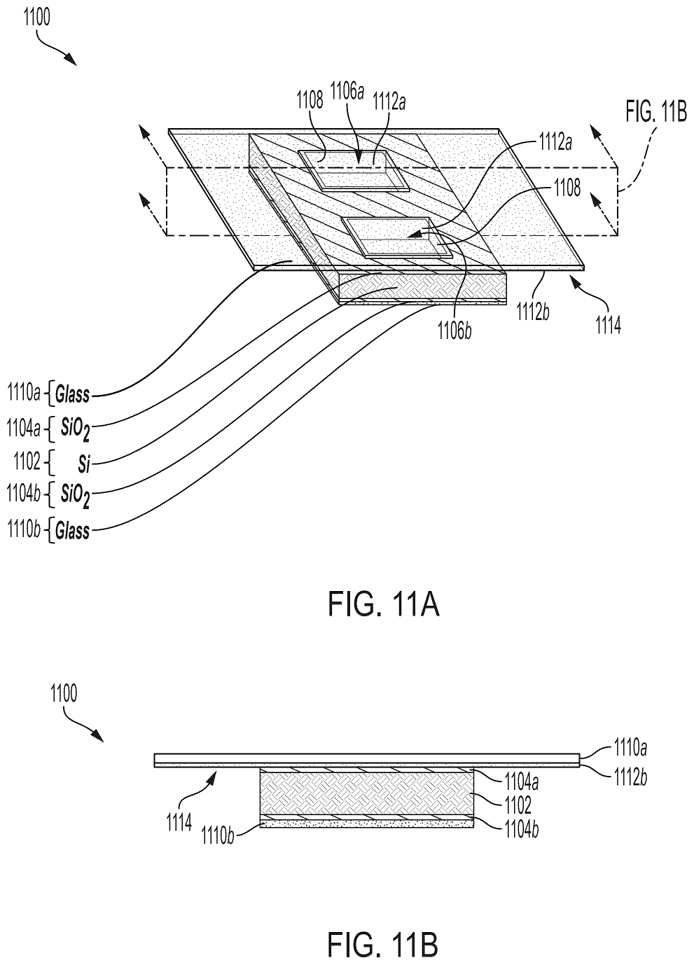

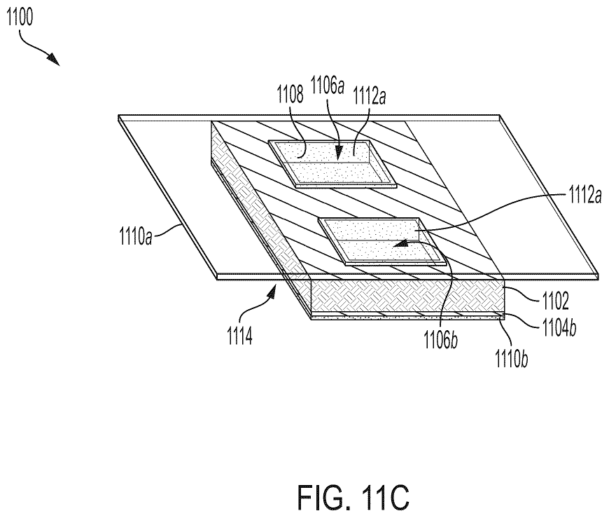

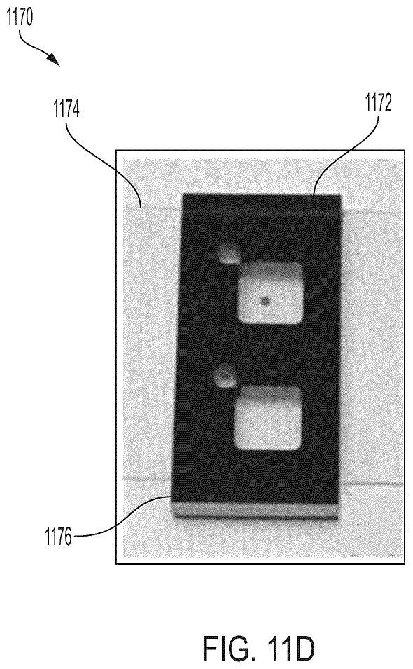

FIG. 11A presents a schematic diagram, in perspective view, of an example vapor cell 1100 during fabrication in which complete OTS coverage is on the glass window and side wall surfaces of a base frame. FIG. 11B presents a schematic diagram, in cross-sectional view, of the example vapor cell 1100 of FIG. 11A. The example vapor cell 1100 may be analogous to the example vapor cells 100, 200 described in relation to FIGS. 1A-2B, and as such, may share features in common with the example vapor cells 100, 200. For instance, the example vapor cell 1100 may include a silicon dielectric body 1102 that serves as a base frame of the example vapor cell 1100. The silicon dielectric body 1102 may include first and second exterior surfaces 1104a, 1104b that define openings for cavities 1106a, 1106b extending through the silicon dielectric body 1102. In some instances, such as shown in FIGS. 11A and 11B, a silicon oxide (SiO₂) layer defines the first and second exterior surfaces 1104a, 1104b. In some instances, a silicon oxide (SiO₂) layer may also define a side wall surface 1108 that forms a perimeter around each of the cavities 1106a, 1106b and is internal to the silicon dielectric body 1102. The example vapor cell 1100 also includes first and second glass windows 1110a, 1110b that are bonded to, respectively, the first and second exterior surfaces 1104a, 1104b of the silicon dielectric body 1102. The first and second glass windows 1110a, 1110b may be formed of, for example, a borosilicate glass material. The example vapor cell 1100 additionally includes a first antirelaxation coating 1112a that is disposed on each of the side wall surfaces 1108. As such, instances of the first antirelaxation coating 1112a are present in each of the cavities 1106a, 1106b. The first antirelaxation coating 1112a includes an organosilane material, such as octadecyltrichlorosilane (OTS). The example vapor cell 1100 also includes a second antirelaxation coating 1112b that is disposed along an underside surface 1114 of the first glass window 1110a. The underside surface 1114 is bonded to the first exterior surface 1104a of the silicon dielectric body 1102. The second antirelaxation coating 1112b covers the entirety of the underside surface 1114 (e.g., the entire portion of the underside surface 1114 not bonded to the first exterior surface 1104a). The second antirelaxation coating 1112b also includes an organosilane material, such as octadecyltrichlorosilane (OTS).

In some implementations, however, the second antirelaxation coating 1112b may be selectively patterned to cover a portion of the underside surface 1114 that is interior to the example vapor cell 1100. FIG. 11C presents a schematic diagram, in perspective view, of the example vapor cell 1100 of FIG. 11A, but during fabrication and in which OTS coats the side wall surfaces and a glass window. In particular, the first glass window 1110a includes first and second portions 1116a, 1116b that cover, respectively, the top openings of the cavities 1106a, 1106b. The second antirelaxation coating 1112b is patterned to cover only the first and second portions 1116a, 1116b of the first glass window 1110a, which are interior to the example vapor cell 1100. FIG. 11D is a photographic image 1170, in perspective view, of an example of an Cs alkali dispensed OTS SAMs-coated vapor cell 1072 with complete OTS coverage on the glass window 1174 and base frame 1176 fabricated using low temperature bonding process. The Cs alkali dispensed OTS SAMs-coated vapor cell 1072 may be analogous to the example vapor cell 1100 described in relation to FIGS. 11A-11C.

In some implementations, fabricating a vapor cell includes the selective laser ablation of Si/SiO₂. Vapor cells for RF sensing, in particular, may be influenced by electric fields that cause shifts and broadening of the spectral lines that reduce sensitivity and accuracy. Moreover, in certain cases, the top glass window bonding process can drive unwanted gases into the vapor cell cavity. Background gases remaining in the vapor cell can broaden the spectral lines. In antirelaxation coated cells that are free of buffer gas, the background gas pressure is thought to be low enough that collisions between atoms and the background gas are not important for magnetometers. However, the high fragility of alkali atoms in highly excited Rydberg states means that collisions between Rydberg atoms (e.g., that have large cross-sections) and background gases can interfere with the sensing process in vapor cell sensor when sensing RF fields. For example, measurements of the mass spectral data for the background gas inside an OTS cell show that some Rb atoms can react with the molecular fragments of the hydrocarbon chains that are present, such as methane (CH₄), methyl (CH₃), methylene (CH₂), HCl, CO₂, C₃H₈, N₂, CO and H₂. A spectroscopic test was conducted of an example vapor cell fabricated using the example process 400 described in relation to FIG. 4. The test was conducted immediately after fabrication in order to evaluate the vapor cell performance by performing saturated absorption spectroscopy measurements on the Cs transition and validate the presence of Cs vapor and low background gas contamination within the vapor cells.

FIG. 12A is graph showing an example of a saturated absorption (SA) spectrum 1200 of a Cs alkali-based OTS coated vapor cell, measured immediately after the sealing of the top glass cavity window. The cavity of the vapor cells showed Cs absorption lines, confirming the presence of Cs vapor in the entire cell. SA spectroscopy can show potential gas contamination in the cell via the collisional broadening of the optical transition. The spectral lines of Cs are normally sharp and well-defined under ideal conditions. However, the fabricated vapor cell shows highly broadened Cs spectral lines indicating pressure broadening due to gas contamination. This broadening may occur because the collisions with gas molecules disturb the energy levels of Cs atoms, leading to a spread in the frequencies emitted or absorbed by Cs atoms during the measurements. Any contamination introduced can exacerbate collisional broadening effects. Gettering the cavity of the Cs-dispensed vapor cells by using getter elements, such as reactive metals like titanium, zirconium and/or TiZr alloy, can be done by placing them inside the cavity. However, in the application of vapor cells for RF sensing, reactive metals like these getter elements can perturb the RF fields, which is undesirable.

In some implementations, fabricating a vapor cell includes a process to getter the residual gas contaminations in the cavity by performing selective laser ablation, such as described in relation to the example process 500 of FIG. 5. This ablation is suitable for integration into MEMs vapor cell manufacturing methodologies to improve the purity of the Cs vapor environment, by reducing the collisional broadening effects. Picosecond lasers can be employed to perform selective ablation by direct absorption in the thin SiO₂/Si layer without damaging the top glass window and its hermetic seal. FIG. 12B presents a schematic diagram that illustrates the ablation process 1230, and a microscopy image of an example laser ablated area 1250 is shown in FIG. 12C.

The process may, for example, include the heating, melting, and vaporization of a thin SiO₂/Si layer. As the laser selectively removes the thin layer, it can locally heat and modify the crystalline silicon structure, producing a porous silicon layer that can getter the background gases. The energy fluence from the laser can induce localized melting and vaporization of SiO₂/Si, leading to the formation of porous silicon structures underneath the ablated SiO₂ regions, forming a plume of vaporized SiO₂, Si, silicon clusters, nanostructures and/or porous silicon. FIG. 12D presents a scanning electron micrograph of an example of a silicon porous layer 1270 formed on a side wall of a silicon wafer. FIG. 12E presents a scanning electron micrograph of the silicon porous layer 1270, but at higher magnification. The magnification in FIG. 12D is at 2000×, while the magnification in FIG. 12E is at 2700×. The silicon porous layer 1270 includes agglomerates of particles (e.g., silicon and/or silicon oxide particles) that have an interconnected, open-pore structure. This structure has a high surface area (e.g., greater than 300 m²/g) that can absorb gas species via processes of physical absorption and/or chemical absorption.

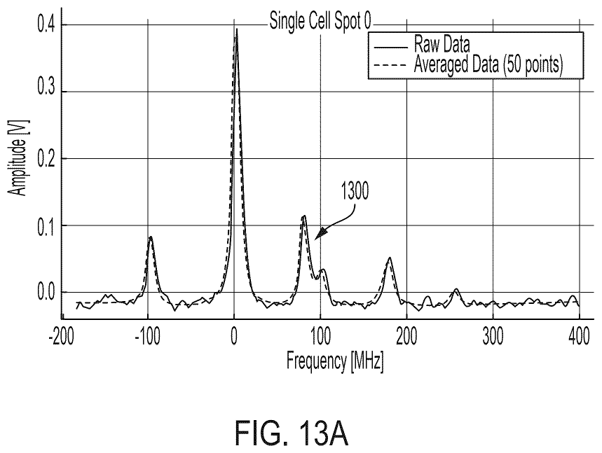

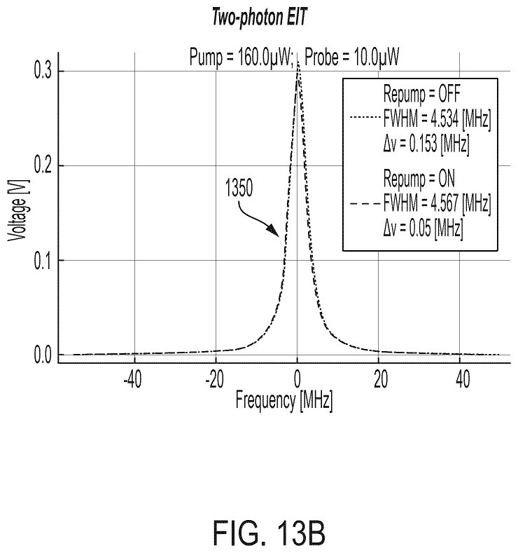

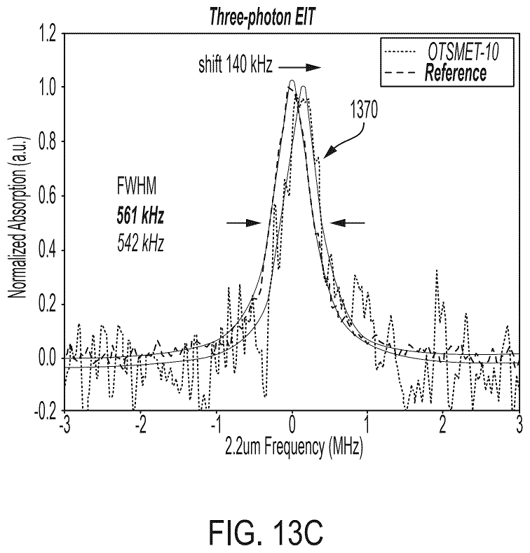

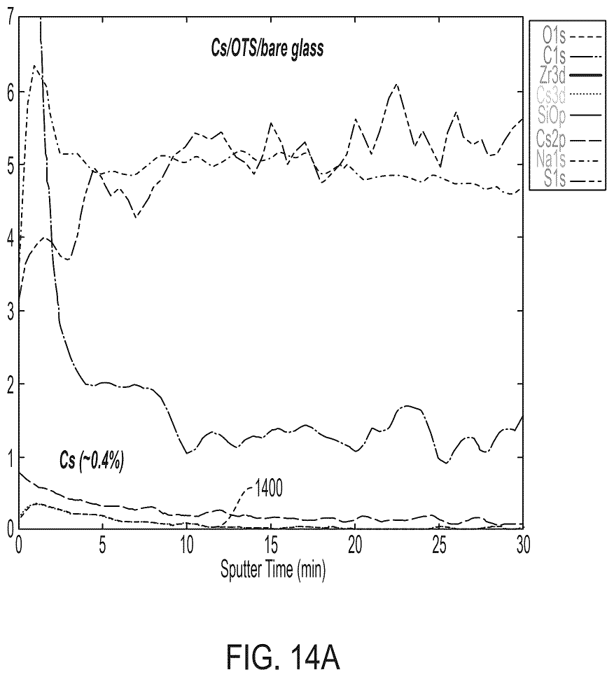

In some implementations, the plume of vaporized SiO₂, Si, silicon clusters, nanostructures and/or porous silicon is ejected into an open space, such as a cavity or channel in the silicon body. The vaporized plume of ejected materials can itself act as a getter that effectively absorbs or reacts with the residual contaminants inside the vapor cell cavity and in turn decrease the background pressure. FIG. 13A shows the measured SA spectrum 1300 of the vapor cell after the selective laser ablation process. The spectrum 1300 is now fully observed with no evidence of collisional broadening at the spectral resolution obtainable using saturated absorption spectroscopy.

FIG. 13B shows the measured electromagnetically induced transparency (EIT) spectrum 1350 of the OTS coated Cs vapor cell measured using a high sensitivity three-photon sensing scheme. By comparison, FIG. 13C shows the measured EIT spectrum 1370 of the same OTS coated Cs vapor cell measured using a high sensitivity a three-photon sensing scheme. The EIT spectra 1350, 1370 are measured to investigate the electric fields inside the vapor cell and their EIT line shapes. The EIT signal will show a Stark shift and broadening in the presence of electric fields. Collisions between alkali-atoms lead to spectral broadening and shifts. Contaminant gases have the effect of broadening and shifting of EIT lines. For the two-photon scheme, an EIT signal is generated for the 50D Rydberg state. For the three-photon sensing scheme, the 895 nm probe laser drives the 6S_{1/2}(F=4)→6P_{1/2} (F=3) transition, the 636 nm intermediate coupling beam drives the 6P_{1/2} (F=3)→9S_{1/2} (F=4) transition, and the 2262 nm Rydberg coupling beam drives the 9S_{1/2} (F=4)→42P_{1/2} transition. FIGS. 13B and 13C show the shape and line width of, respectively, the two-photon and three-photon signal 1350, 1370 measured for the OTS coated vapor cell. The results are compared to a large glass blown reference cell. The line shifts between the reference vapor cell and the OTS coated MEMs vapor cells are negligible as are the linewidths. Linewidths smaller than 350 kHz can be obtained. The linewidths in FIGS. 13B and 13C may, in certain cases, be limited by the optical setup.

For the two-photon scheme, the fabricated OTS coated vapor cell yields an EIT linewidth of 4.5 MHz that is experimentally identical to a reference commercial vapor cell within the error of the experiments. There is no shift or asymmetries measurable in the EIT line shape compared to the reference vapor cell. Furthermore, using the narrow line width setup provided by three-photon Doppler free sensing system, an approximately Lorentzian shape with a 542 kHz full-width at half maximum (FWHM) with no discernible shift is observed in FIG. 13C. For comparison, the line shape of the EIT signal is measured with a FWHM of 561±10 KHz in a standard commercial glass Cs vapor cell.

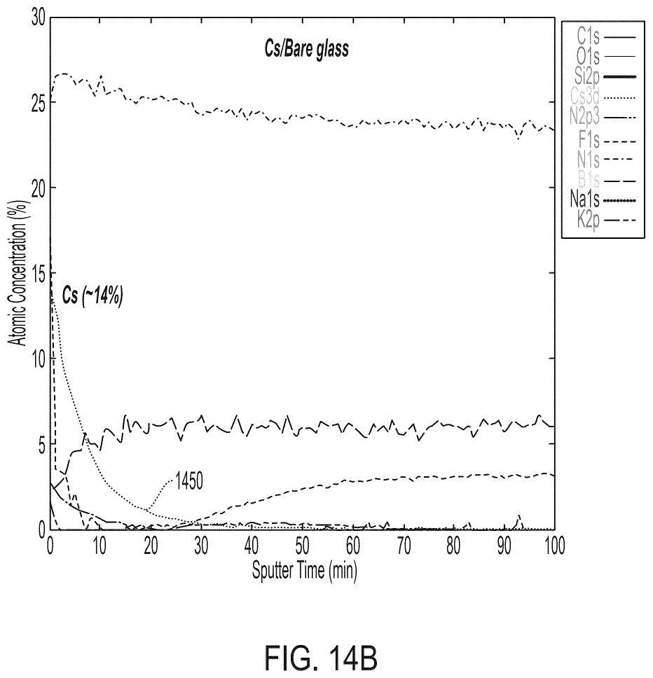

X-ray photoelectron spectroscopy (XPS) can provide valuable insights into the surface chemical composition, allowing the modifications of the surface and near-surface regions of materials to be examined, making XPS suitable for investigating the Cs interaction with the OTS coated SiO₂/Si and top glass window. With a probing depth of only a few nm, XPS is highly sensitive to reveal the chemistry of the outmost layer (e.g., OTS SAMs), where Cs alkali sticking occurs. FIGS. 14A and 14B show the results of XPS depth profiling studies on surfaces of interest to prove that the surfaces have been modified. XPS depth profiling reveals significantly reduced Cs adhesion and/or stiction on an OTS functionalized top glass window surface (FIG. 14A) compared to the uncoated surface (FIG. 14B). This difference underscores the passivation (e.g., chemically inert) provided by the alkyl chains in the OTS SAMs, which inhibit the Cs adsorption by reducing the ability of Cs to chemically react with the surface. The depth profiling spectra 1400, 1450 show minimal presence of Cs (e.g., Cs3d) in the near surface region of OTS coated glass compared to the bare glass. This result also correlates with the contact angle measurements using Cs droplets (e.g., FIGS. 10A-10B), where the OTS functionalized glass substrates exhibited highly hydrophobic nature showing contact angles of at least 100°. In contrast, and as shown in FIG. 14B, the uncoated glass substrate shows a stronger Cs signal at the surface suggesting stronger interaction with the surface.

In some aspects of what is described, a vapor cell may also be described by the following examples:
Example 1. A vapor cell, comprising:
   a dielectric body comprising:
      an interior surface that defines a cavity in the dielectric body, and
      an exterior surface that defines an opening to the cavity;
   an antirelaxation coating disposed on the interior surface of the dielectric body and comprising an organosilane material;
   a vapor or a source of vapor residing in the cavity, the vapor or the source of vapor comprising alkali metal atoms; and
   an optical window covering the opening and having a surface bonded to the exterior surface of the dielectric body to form a seal around the opening.
Example 2. The vapor cell of example 1, wherein the organosilane material comprises organosilane molecules that have:
   a head group comprising a silicon atom;
   a terminal group; and
   a spacer chain extending between the head group and the terminal group.
Example 3. The vapor cell of example 2, wherein the head group is configured to react with the interior surface, thereby adsorbing the organosilane molecules onto the interior surface.
Example 4. The vapor cell of example 2 or example 3, wherein the silicon atom has a first bond to the spacer chain and a second bond to a chlorine atom or an alkoxy group.
Example 5. The vapor cell of example 4, wherein the head group is a trichlorosilane group, a methyldichlorosilane group, a dimethylchlorosilane group, or a triethoxysilane group.
Example 6. The vapor cell of example 2 or any one of examples 3-5, wherein the terminal group comprises a carbon atom that has a first bond to the spacer chain and a second bond to a hydrogen atom or a fluorine atom.
Example 7. The vapor cell of example 6, wherein the terminal group is a methyl group or a trifluoromethyl group.
Example 8. The vapor cell of example 2 or any one of examples 3-7, wherein the spacer chain comprises an alkane chain that has one or both of a carbon-hydrogen bond and a carbon-fluorine bond.
Example 9. The vapor cell of example 1 or any one of examples 2-8, wherein the organosilane material comprises organosilane molecules that have a composition represented by CH₃(CH₂)ₓSiCl₃, where x is an integer in a range from 4 to 100.
Example 10. The vapor cell of example 1 or any one of examples 2-9, wherein the organosilane material is defined by a monolayer of organosilane molecules on the interior surface.
Example 11. The vapor cell of example 1 or any one of examples 2-10, wherein the dielectric body comprises a metal oxide layer that defines the interior surface.
Example 12. The vapor cell of example 11, wherein the metal oxide layer is a silicon oxide layer.
Example 13. The vapor cell of example 1 or any one of examples 2-10, wherein the dielectric body is formed of a metal oxide material.
Example 14. The vapor cell of example 13, wherein the metal oxide material is a glass that comprises silicon oxide.
Example 15. The vapor cell of example 1 or any one of examples 2-14,
   wherein the surface of the optical window comprises a covering portion that extends across the opening of the cavity; and
   wherein a second antirelaxation coating is disposed on the covering portion and comprises the organosilane material.
Example 16. The vapor cell of example 1 or example 2-15, comprising:
   the source of vapor, disposed in the cavity and comprising a liquid or solid source of the alkali metal atoms, the liquid or solid source configured to generate a vapor of the alkali metal atoms when heated or irradiated.
Example 17. The vapor cell of example 16,
   wherein the cavity comprises a first chamber, a second chamber, and a channel that fluidly couples the first chamber to the second chamber; and
   wherein the source of vapor is disposed in the second chamber of the cavity.
Example 18. The vapor cell of example 1 or any one of examples 2-17, wherein the seal comprises a metal oxynitride layer disposed along an interface between the exterior surface of the dielectric body and the surface of the optical window.

In some aspects of what is described, a method of manufacturing a vapor cell may be described by the following examples:
Example 19. A method of manufacturing a vapor cell, comprising:
   obtaining a dielectric body that comprises:
      an interior surface that defines a cavity in the dielectric body, and
      an exterior surface that defines an opening to the cavity;
   forming an antirelaxation coating on the interior surface of the dielectric body, the antirelaxation coating comprising an organosilane material;
   disposing a vapor or a source of vapor in the cavity, the vapor or the source of vapor comprising alkali metal atoms;
   obtaining an optical window that comprises a surface; and
   bonding the surface of the optical window to the exterior surface of the dielectric body to form a seal around the opening to the cavity.
Example 20. The method of example 19, comprising:
   before forming the antirelaxation coating, contacting the interior surface with an etchant to reduce a surface roughness of the interior surface.
Example 21. The method of example 20, wherein the interior surface, after contact with the etchant, has a surface roughness no greater than 5 nm.
Example 22. The method of example 19 or any one of examples 20-21,
   wherein the interior surface of the dielectric body comprises hydroxyl ligands; and
   wherein forming the antirelaxation coating comprises contacting the interior surface with a solution having organosilane molecules dissolved therein, the organosilane molecules reacting with the hydroxyl ligands to form the organosilane material.
Example 23. The method of example 22, wherein forming the antirelaxation coating comprises:
   separating the interior surface from the solution; and
   heating the interior surface to a temperature between 100° C. and 150° C.
Example 24. The method of example 19 or any one of examples 20-23, wherein the organosilane material comprises organosilane molecules that have:
   a head group comprising a silicon atom;
   a terminal group; and
   a spacer chain extending between the head group and the terminal group.
Example 25. The method of example 24, wherein the head group is configured to react with the interior surface, thereby adsorbing the organosilane molecules onto the interior surface.
Example 26. The method of example 24 or example 25, wherein the silicon atom has a first bond to the spacer chain and a second bond to a chlorine atom or an alkoxy group.
Example 27. The method of example 26, wherein the head group is a trichlorosilane group, a methyldichlorosilane group, a dimethylchlorosilane group, or a triethoxysilane group.
Example 28. The method of example 24 or any one of examples 25-27, wherein the terminal group comprises a carbon atom that has a first bond to the spacer chain and a second bond to a hydrogen atom or a fluorine atom.
Example 29. The method of example 28, wherein the terminal group is a methyl group or a trifluoromethyl group.
Example 30. The method of example 24 or any one of examples 25-29, wherein the spacer chain comprises an alkane chain that has one or both of a carbon-hydrogen bond and a carbon-fluorine bond.
Example 31. The method of example 19 or any one of examples 20-30, wherein the organosilane material comprises organosilane molecules that have a composition represented by CH₃(CH₂)ₓSiCl₃, where x is an integer in a range from 4 to 100.
Example 32. The method of example 19 or any one of examples 20-31, wherein forming the antirelaxation coating comprises forming a monolayer of organosilane molecules on the interior surface.
Example 33. The method of example 19 or any one of examples 20-32, comprising: forming a metal oxide layer on the dielectric body to define the interior surface.
Example 34. The method of example 33, wherein the metal oxide layer is a silicon oxide layer.
Example 35. The method of example 19 or any one of examples 20-32, wherein the dielectric body is formed of a metal oxide material.
Example 36. The method of example 35, wherein the metal oxide material is a glass that comprises silicon oxide.
Example 37. The method of example 19 or any one of examples 20-36,
   wherein the surface of the optical window comprises a covering portion that extends across the opening of the cavity; and
   wherein the method comprises forming a second antirelaxation coating on the covering portion, the second antirelaxation coating comprising the organosilane material.
Example 38. The method of example 19 or any one of examples 20-37,
   wherein the source of vapor is disposed in the cavity;
   wherein the source of vapor comprises a liquid or solid source of the alkali metal atoms, the liquid or solid source configured to generate a vapor of the alkali metal atoms when heated or irradiated; and
   wherein the method comprises heating or irradiating the source of vapor after the seal is formed.
Example 39. The method of example 38,
   wherein the cavity comprises a first chamber, a second chamber, and a channel that fluidly couples the first chamber to the second chamber; and
   wherein the source of vapor is disposed in the second chamber of the cavity.
Example 40. The method of example 19 or any one of examples 20-39, wherein bonding the surface of the optical window to the exterior surface of the dielectric body comprises:
   exposing the surface of the optical window and the exterior surface of the dielectric body to a sequence of plasmas to produce respective altered surfaces, the sequence of plasmas comprising an oxygen plasma and a nitrogen plasma; and
   contacting the altered surfaces to each other to form the seal, the seal comprising a metal oxynitride layer that is formed along an interface between the altered surfaces.
Example 41. The method of example 19 or any one of examples 20-40, wherein bonding the surface of the optical window to the exterior surface of the dielectric body comprises covering the opening of the cavity with the optical window to enclose the cavity.

In some aspects of what is described, a method of manufacturing a vapor cell may be described by the following examples:
Example 42. A method of manufacturing a vapor cell, comprising:
   obtaining a dielectric body comprising:
      an interior surface that defines a cavity in the dielectric body, and
      an exterior surface that defines an opening to the cavity;
   disposing a vapor or a source of vapor in the cavity, the vapor or the source of vapor comprising alkali metal atoms;
   obtaining an optical window that comprises a surface;
   bonding the surface of the optical window to the exterior surface of the dielectric body to form a bonded interface of the vapor cell, the bonded interface comprising a seal around the opening to the cavity; and
   ablating, by operation of laser light, material from the exterior surface of the dielectric body to form a channel therein, the channel comprising a porous layer that is configured to absorb a gas species from the cavity.
Example 43. The method of example 42, comprising:
   absorbing the gas species from the cavity onto a surface of the porous layer.
Example 44. The method of example 43, wherein absorbing the gas species comprises absorbing water vapor from the cavity onto the surface of the porous layer.
Example 45. The method of example 42 or any one of examples 43-44, wherein ablating material from the exterior surface comprises:
   generating a heated material along a portion of the bonded interface; and
   cooling the heated material in the channel to form the porous layer.
Example 46. The method of example 45, wherein generating the heated material comprises reacting at least a portion of the gas species with the heated material, thereby reducing an amount of the gas species in the cavity.
Example 47. The method of example 42 or any one of examples 43-44,
   wherein the gas species is a first gas species; and
   wherein ablating material from the exterior surface comprises:
      generating a heated material along a portion of the bonded interface;
      cooling a first portion of the heated material in the channel to form the porous layer; and
      ejecting a second portion of the heated material into the cavity, the second portion configured to absorb a second gas species from the cavity.
Example 48. The method of example 47, wherein generating the heated material comprises reacting at least a portion of the first or second gas species with the heated material, thereby reducing an amount of the first or second gas species in the cavity.
Example 49. The method of example 47, comprising one or both of:
   absorbing the first gas species from the cavity onto a surface of the porous layer; and
   absorbing the second gas species from the cavity onto a surface of the second portion of heated material.
Example 50. The method of example 49, wherein absorbing the second gas species comprises absorbing water vapor from the cavity onto the surface of the second portion of heated material.
Example 51. The method of example 42 or any one of examples 43-50, wherein the channel extends along a portion of the bonded interface between an open channel end and a closed channel end, and the open channel end is adjacent to the cavity.
Example 52. The method of example 42 or any one of examples 43-51, wherein the porous layer completely fills the channel.
Example 53. The method of example 42 or any one of examples 43-52, wherein the porous layer has a surface area of at least 300 m²/g.
Example 54. The method of example 42 or any one of examples 43-53, wherein the channel has a depth in the dielectric body that is no greater than 500 μm.
Example 55. The method of example 42 or any one of examples 43-54, comprising:
   before bonding, disposing an antirelaxation coating on one or more surfaces of the cavity.
Example 56. The method of example 55,
   wherein the surface of the optical window comprises a covering portion that extends across the opening of the cavity; and
   wherein the method comprises disposing a second antirelaxation coating on the covering portion before bonding the surface of the optical window to the exterior surface of the dielectric body.
Example 57. The method of example 42 or any one of examples 43-56,
   wherein the source of vapor is disposed in the cavity;
   wherein the source of vapor comprises a liquid or solid source of the alkali metal atoms, the liquid or solid source configured to generate a vapor of the alkali metal atoms when heated or irradiated; and
   wherein the method comprises heating or irradiating the source of vapor after the seal is formed.
Example 58. The method of example 57,
   wherein the cavity comprises a first chamber, a second chamber, and a second channel that fluidly couples the first chamber to the second chamber;
   wherein the source of vapor is disposed in the second chamber of the cavity.
Example 59. The method of example 42 or any one of examples 43-58, wherein bonding the surface of the optical window to the exterior surface of the dielectric body comprises:
   exposing the surface of the optical window and the exterior surface of the dielectric body to a sequence of plasmas to produce respective altered surfaces, the sequence of plasmas comprising an oxygen plasma and a nitrogen plasma; and
   contacting the altered surfaces to each other to form the bonded interface, the seal comprising comprises a metal oxynitride layer disposed along the bonded interface.
Example 60. The method of example 42 or any one of examples 43-59, wherein bonding the surface of the optical window to the exterior surface of the dielectric body comprises covering the opening of the cavity with the optical window to enclose the cavity.

In some aspects of what is described, a vapor cell may also be described by the following examples:
Example 61. A vapor cell, comprising:
   a dielectric body comprising:
      an interior surface that defines a cavity in the dielectric body,
      an exterior surface that defines an opening to the cavity, and
      a channel comprising a porous layer that is configured to absorb a gas species from the cavity;
   a vapor or a source of vapor residing in the cavity, the vapor or the source of vapor comprising alkali metal atoms; and
   an optical window covering the opening and having a surface bonded to the exterior surface of the dielectric body to form a bonded interface of the vapor cell, the bonded interface comprising a seal around the opening.
Example 62. The vapor cell of example 61, wherein the channel extends along a portion of the bonded interface between an open channel end and a closed channel end, the open channel end adjacent to the cavity.
Example 63. The vapor cell of example 61 or example 62, wherein the porous layer completely fills the channel.
Example 64. The vapor cell of example 61 or any one of examples 62-63, wherein the porous layer has a surface area of at least 300 m²/g.
Example 65. The vapor cell of example 61 or any one of examples 62-64, wherein the channel has a depth in the dielectric body that is no greater than 500 μm.
Example 66. The vapor cell of example 61 or any one of examples 62-65, wherein the porous layer is configured to absorb water vapor from the cavity.
Example 67. The vapor cell of example 61 or any one of examples 62-66,
   wherein the channel is formed by ablating the exterior surface of the dielectric body with laser light along the bonded interface, thereby generating a heated material; and
   wherein the porous layer is formed by the heated material upon cooling.
Example 68. The vapor cell of example 61 or any one of examples 62-66,
   wherein the channel is formed by ablating the exterior surface of the dielectric body with laser light along the bonded interface, thereby generating a heated material;
   wherein the porous layer is formed by a first portion of the heated material upon cooling; and
   wherein a second portion of the heated material is ejected into the cavity and operable to absorb a second gas species from the cavity.
Example 69. The vapor cell of example 68, wherein the second portion of the heated material is configured to absorb water vapor from the cavity.
Example 70. The vapor cell of example 61 or any one of examples 62-69, comprising an antirelaxation coating disposed on one or more surfaces of the cavity.
Example 71. The vapor cell of example 70,
   wherein the surface of the optical window comprises a covering portion that extends across the opening of the cavity; and
   wherein a second antirelaxation coating is disposed on the covering portion.
Example 72. The vapor cell of example 61 or any one of examples 62-71, comprising:
   the source of vapor, disposed in the cavity and comprising a liquid or solid source of the alkali metal atoms, the liquid or solid source configured to generate a vapor of the alkali metal atoms when heated or irradiated.
Example 73. The vapor cell of example 72,
   wherein the cavity comprises a first chamber, a second chamber, and a second channel that fluidly couples the first chamber to the second chamber; and
   wherein the source of vapor is disposed in the second chamber of the cavity.
Example 74. The vapor cell of example 61 or any one of examples 62-73, wherein the seal comprises a metal oxynitride layer disposed along the bonded interface.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple embodiments separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

What is claimed is:

1. A vapor cell, comprising:
a dielectric body comprising:
an interior surface that defines a cavity in the dielectric body, and
an exterior surface that defines an opening to the cavity;
an antirelaxation coating disposed on the interior surface of the dielectric body and comprising an organosilane material;
a vapor or a source of vapor residing in the cavity, the vapor or the source of vapor comprising alkali metal atoms; and
an optical window covering the opening and having a surface bonded to the exterior surface of the dielectric body to form a seal around the opening.

2. The vapor cell of claim 1, wherein the organosilane material comprises organosilane molecules that have:
a head group comprising a silicon atom;
a terminal group; and
a spacer chain extending between the head group and the terminal group.

3. The vapor cell of claim 2, wherein the head group is configured to react with the interior surface, thereby adsorbing the organosilane molecules onto the interior surface.

4. The vapor cell of claim 2, wherein the silicon atom has a first bond to the spacer chain and a second bond to a chlorine atom or an alkoxy group.

5. The vapor cell of claim 4, wherein the head group is a trichlorosilane group, a methyldichlorosilane group, a dimethylchlorosilane group, or a triethoxysilane group.

6. The vapor cell of claim 2, wherein the terminal group comprises a carbon atom that has a first bond to the spacer chain and a second bond to a hydrogen atom or a fluorine atom.

7. The vapor cell of claim 6, wherein the terminal group is a methyl group or a trifluoromethyl group.

8. The vapor cell of claim 2, wherein the spacer chain comprises an alkane chain that has one or both of a carbon-hydrogen bond and a carbon-fluorine bond.

9. The vapor cell of claim 1, wherein the organosilane material comprises organosilane molecules that have a composition represented by CH₃(CH₂)ₓSiCl₃, where x is an integer in a range from 4 to 100.

10. The vapor cell of claim 1, wherein the organosilane material is defined by a monolayer of organosilane molecules on the interior surface.

11. The vapor cell of claim 1, wherein the dielectric body comprises a metal oxide layer that defines the interior surface.

12. The vapor cell of claim 11, wherein the metal oxide layer is a silicon oxide layer.

13. The vapor cell of claim 1, wherein the dielectric body is formed of a metal oxide material.

14. The vapor cell of claim 13, wherein the metal oxide material is a glass that comprises silicon oxide.

15. The vapor cell of claim 1,
wherein the surface of the optical window comprises a covering portion that extends across the opening of the cavity; and
wherein a second antirelaxation coating is disposed on the covering portion and comprises the organosilane material.

16. The vapor cell of claim 1, comprising:
the source of vapor, disposed in the cavity and comprising a liquid or solid source of the alkali metal atoms, the liquid or solid source configured to generate a vapor of the alkali metal atoms when heated or irradiated.

17. The vapor cell of claim 16,
wherein the cavity comprises a first chamber, a second chamber, and a channel that fluidly couples the first chamber to the second chamber; and
wherein the source of vapor is disposed in the second chamber of the cavity.

18. The vapor cell of claim 1, wherein the seal comprises a metal oxynitride layer disposed along an interface between the exterior surface of the dielectric body and the surface of the optical window.
